(19) United States
(12) Patent Application Publication
(10) Pub. No.: US 2022/0391554 A1
(43) Pub. Date: Dec. 8, 2022

(54) MULTI-AGENT SIMULATION SYSTEM AND METHOD

(71) Applicant: TOYOTA JIDOSHA KABUSHIKI KAISHA, Toyota-shi (JP)

(72) Inventors: Takatomo TORIGOE, Yokohama-shi (JP); Akira YOSHIOKA, Bunkyo-ku (JP); Masahiro KUWAHARA, Kasukabe-shi (JP); Hiroaki KIMURA, Edogawa-ku (JP)

(21) Appl. No.: 17/662,163

(22) Filed: May 5, 2022

(30) Foreign Application Priority Data
Jun. 8, 2021 (JP) 2021-095947

(51) Int. Cl. G06F 30/15; G06F 30/3308

(52) U.S. Cl. CPC G06F 30/15; G06F 30/3308

(57) ABSTRACT

The multi-agent simulation system includes a plurality of agent simulators provided for each of a plurality of agents and a center controller. The plurality of agent simulators simulate a state of each of the plurality of agents while causing the plurality of agents to interact with each other by exchange of messages. The center controller relays transmission and reception of messages between the plurality of agent simulators. The plurality of agents include a plurality of types of agents including types having different time granularity. Each of the plurality of agent simulators transmits a message to the center controller at a transmission time interval corresponding to time granularity of a target agent to be simulated.

### CROSS-REFERENCE TO RELATED APPLICATION

The present application claims priority under 35 U.S.C. § 119 to Japanese Patent Application No. 2021-095947, filed Jun. 8, 2021, the contents of which application are incorporated herein by reference in their entirety.

### BACKGROUND

### Field

The present disclosure relates to a multi-agent simulation system and a multi-agent simulation method for simulating a target world using a plurality of agents interacting with each other.

### Background Art

Multi-agent simulation is known. The multi-agent simulation is to simulate a target world using a plurality of agents interacting with each other. For example, WO2011/018854 discloses a simulator which simulates the behavior of an agent by referring to the agent information of another agent and executes updating the agent information repeatedly. This simulator, in the process of simulating the behavior of the agent, reduces communication traffic by transmitting and receiving only agent information satisfying the condition of a reference agent to be referred to between computers.

As documents showing the state of the art as of the filing of the present application in the technical field of the present disclosure, JP2011-048757A and WO2015/132893 can be exemplified in addition to WO2011/018854.

### SUMMARY

In conventional multi-agent simulation, simulation of each agent is performed at the same processing time interval between agents. On the other hand, depending on a target world to be simulated, various types of agents may be desired to appear. Also, the state change rate of an object represented by an agent may vary depending on the type. If simulations are performed between agents at the same processing time intervals, the processing time interval of each agent is set in accordance with an object whose state change rate is the fastest in order to maintain performance of the multi-agent simulation.

However, in this case, in an agent representing an object whose state change rate is slow, calculation is performed at a processing time interval shorter than a necessary processing time interval. In the multi-agent simulation, the interaction between agents is accomplished by exchanging messages. The shorter the processing time interval, the shorter the message transmission time interval, and the larger the amount of messages in the system as a whole, thus wasting computing resources.

The present disclosure has been made in view of the above-described problems. It is an object of the present disclosure to provide a multi-agent simulation system and a multi-agent simulation method that can reduce the increase in the amount of messages exchanged for interaction between agents while maintaining performance of the multi-agent simulation.

The present disclosure provides a multi-agent simulation system that simulates a target world using a plurality of agents interacting with each other. The system of the present disclosure comprises a plurality of agent simulators provided for each of the plurality of agents and a center controller communicating with the plurality of agent simulators. The plurality of agent simulators are programmed to simulate a state of each of the plurality of agents while causing the plurality of agents to interact with each other by exchange of messages. The center controller is programmed to communicate with the plurality of agent simulators to relay transmission and reception of the messages between the plurality of agent simulators. Here, the plurality of agents include a plurality of types of agents including types having different time granularity. Each of the plurality of agent simulators is programmed to transmit a message to the center controller at a transmission time interval corresponding to time granularity of a target agent to be simulated.

In the system of the present disclosure, the center controller may transmit the messages received from each of the plurality of agent simulators at a same time interval as a time interval at which the messages are received. The center controller may also transmit the messages received from each of the plurality of agent simulators by a broadcast. When the plurality of types of agents include a person operated by a VR system, each of the plurality of agent simulators may execute a simulation in real time.

The present disclosure provides a multi-agent simulation method for simulating a target world using a plurality of agents interacting with each other. The method of the present disclosure is performed using a plurality of agent simulators provided for each of the plurality of agents and a center controller communicating with the plurality of agent simulators. The method of the present disclosure comprises exchanging messages between the plurality of agent simulators, simulating a state of each of the plurality of agents while causing the plurality of agents to interact with each other by exchange of the messages, and relaying transmission and reception of the messages between the plurality of agent simulators by the center controller. The plurality of agents include a plurality of types of agents including types having different time granularity. The method of the present disclosure comprises causing each of the plurality of agent simulators to transmit a message to the center controller at a transmission time interval corresponding to time granularity of a target agent to be simulated.

The method of the present disclosure may comprise causing the center controller to transmit the messages received from each of the plurality of agent simulators at a same time interval as a time interval at which the messages are received. The method of the present disclosure may comprise causing the center controller to transmit the messages received from each of the plurality of agent simulators by a broadcast. The method of the present disclosure may comprise causing each of the plurality of agent simulators to execute a simulation in real time when the plurality of types of agents include a person operated by a VR system.

In the multi-agent simulation system and method of the present disclosure, the time granularity of the agents in the target world to be simulated is not single, and there are agents with different time granularity. According to the multi-agent simulation system and method of the present disclosure, the agent simulators transmit messages at a transmission time interval corresponding to the time granularity of the agent to be simulated, rather than at the same transmission time interval between the agent simulators. This can reduce the increase in the amount of messages exchanged between the agent simulators while maintaining the performance of the multi-agent simulation.

### BRIEF DESCRIPTION OF THE DRAWINGS

FIG. 1 is a diagram illustrating an overview of a multi-agent simulation system according to an embodiment of the present disclosure.

FIG. 2 is a diagram illustrating the overview of the multi-agent simulation system according to the embodiment of the present disclosure.

FIG. 3 is a diagram illustrating the overview of the multi-agent simulation system according to the embodiment of the present disclosure.

FIG. 4 is a block diagram illustrating an overall configuration and flows of information of the multi-agent simulation system according to the embodiment of the present disclosure.

FIG. 5 is a block diagram illustrating a configuration and flows of information of an agent simulator for a pedestrian agent according to the embodiment of the present disclosure.

FIG. 6 is a block diagram illustrating a configuration and flows of information of an agent simulator for an autonomous mobile agent according to the embodiment of the present disclosure.

FIG. 7 is a block diagram illustrating a configuration and flows of information of an agent simulator for a VR pedestrian agent according to the embodiment of the present disclosure.

FIG. 8 is a block diagram illustrating a configuration and flows of information of an agent simulator for a roadside sensor agent according to the embodiment of the present disclosure.

FIG. 9 is a block diagram illustrating an example of a configuration of a movement message dispatcher and flows of information according to the embodiment of the present disclosure.

FIG. 10 is a block diagram illustrating a configuration for aggregation and evaluation of simulation results by the multi-agent simulation system according to the embodiment of the present disclosure.

FIG. 11 is a diagram illustrating an example of a physical configuration of the multi-agent simulation system according to the embodiment of the present disclosure.

### DETAILED DESCRIPTION

Hereunder, an embodiment of the present disclosure will be described with reference to the drawings. Note that when the numerals of numbers, quantities, amounts, ranges and the like of respective elements are mentioned in the embodiment shown as follows, the present disclosure is not limited to the mentioned numerals unless specially explicitly described otherwise, or unless the disclosure is explicitly designated by the numerals theoretically. Furthermore, structures and processes that are described in the embodiments shown as follows are not always indispensable to the disclosure unless specially explicitly shown otherwise, or unless the disclosure is explicitly designated by the structures or the processes theoretically.

### 1. Overview of Multi-Agent Simulation System

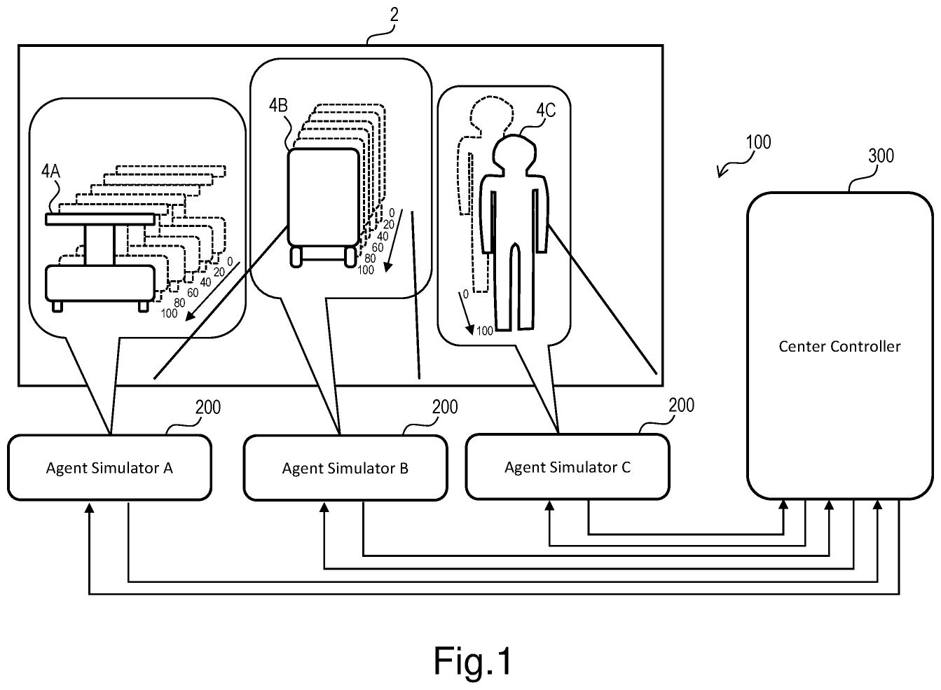

Referring to FIGS. 1 to 3, an overview of a multi-agent simulation system according to an embodiment of the present disclosure will be described. Hereafter, the multi-agent simulation system is abbreviated as the MAS system.

### 1-1. Overview of Configuration and Functions of MAS System

FIG. 1 shows a schematic configuration of the MAS system 100 of the present embodiment. The MAS system 100 simulates a world (simulation target world) 2 which is the target of simulation by causing a plurality of agents 4A, 4B, 4C to interact with each other. The simulation target world by the MAS system of the present disclosure is not limited. However, the simulation target world 2 of the MAS system 100 of the present embodiment is a world in which a person coexists with an autonomous mobile, for example, a robot or a vehicle and can receive various services using the autonomous mobile. The services provided in the simulation target world 2 include, for example, mobility services such as on-demand buses and ferry type buses using autonomous traveling vehicles, and logistics services for delivering packages using autonomous mobile robots.

The simulation target world 2 is comprised of a large number of and many types of agents. The agents comprising the simulation target world 2 include an agent representing a moving object and an agent representing a non-moving object. Examples of moving objects represented as agents are pedestrians, robots, low-speed mobiles, vehicles, pedestrians in which real people participate using VR systems, elevators, etc. Examples of non-moving objects represented as agents are sensors including a camera, automatic doors, etc.

However, in FIG. 1, only three agents 4A, 4B, 4C are shown in the simulation target world 2 for the purpose of illustration. Of these, the agents 4A, 4B represent robots, and the agent 4C represents a pedestrian. That is, in the simulation target world 2 shown in FIG. 1, two types of agents robot and pedestrian are represented. Although the agent 4A and the agent 4B belong to the same category of robot, they differ in size, shape, traveling speed, and motion. Therefore, there are differences between the agent 4A and the agent 4B in the visual information that the agent 4C, which is a pedestrian, can obtain from them. Hereafter, in this specification, the agent 4A is simply referred to as agent A. Similarly, the agent 4B is simply referred to as agent B, and the agent 4C is simply referred to as agent C. In the following, the simulation target world 2, which is a virtual world, is called the virtual world 2 to distinguish it from the real world.

The MAS system 100 includes a plurality of agent simulators 200. The agent simulator 200 is provided for each agent A, B, C. In the following, when distinguishing each agent simulator 200, the agent simulator 200 that simulates the state of the agent A is referred to as agent simulator A. Similarly, the agent simulator 200 that simulates the state of agents B, C is referred to as agent simulators B, C. Each agent simulator 200 has a different configuration depending on the type of the agent to be targeted. For example, the agent simulators B, C of the robot agents B, C have similar configurations, but the agent simulator A of the pedestrian agent A has a different configuration from the agent simulators B, C. The configuration of the agent simulator 200 for each agent type will be described in detail later.

The agent simulator 200 simulates the state of each agent A, B, C while causing them to interact with each other by the exchange of messages. The messages exchanged between the agent simulators 200 contain movement information, which is information on the location and movement of the agent within the virtual world 2. The movement information includes information on the current state and the future plan for the location and movement of the agent. The Information on the current state is, for example, the location, direction, speed, and acceleration at the current time. The Information on the future plan is, for example, a list of locations, directions, speeds, and accelerations at future times. Hereinafter, messages relating to the location and movement of agents exchanged between the agent simulators 200 are referred to as movement messages.

The agent simulator 200 calculates the state of the target agent (ego-agent) to be simulated based on the states of surrounding agents. The surrounding agents are interactive agents that exist around the ego-agent and interact with the ego-agent. The information representing the states of the surrounding agent is movement messages. Each agent simulator 200 can grasp the states of the surrounding agents by exchanging movement messages with other agent simulators 200.

In the example shown in FIG. 1, the agent simulator A grasps the states of the agents B and C from movement messages received from the agent simulators B and C, and updates the states of the agents A based on the states of the agents B and C. The agent simulator A transmits a movement message representing the updated state of the agent A to the agent simulators B and C. Similar processing is also performed in the agent simulators B and C. Thus, the states of the agents A, B, and C are simulated while the agents A, B, and C interact with each other.

The update method of the state of the agent by the agent simulator 200 includes a method of updating the state at regular time intervals and a method of updating the state when some event is detected. However, the latter method also forces an event to be generated to update the state at regular intervals because the effect on the surrounding agents is large if the state is not updated too long. The time interval between agent state updates by the agent simulator 200 is called time granularity.

A number of agents exist in the virtual world 2 which is the target of simulation by the MAS system 100. However, their time granularity is not identical. If the time granularity of all agents is the same, the time granularity of each agent must be set in accordance with an object whose state change rate is the fastest in order to maintain performance of the MAS. However, in this case, in an agent representing an object whose state change rate is slow, calculation is performed at a time granularity smaller than a necessary time granularity. In the MAS, the interaction between agents is performed by the exchange of movement messages, so as the time granularity becomes smaller, the transmission time interval of movement messages becomes shorter accordingly. As a result, the amount of movement messages increases as a whole system and consumes computational resources wastefully.

Therefore, in the MAS system 100, the time granularity of the agent varies depending on the agent type. For example, the pedestrian's walking speed in the real world is about 1 m/sec. Therefore, if the agent is a pedestrian, the time granularity may be on the order of 1 sec or 100 msec. On the other hand, if the agent is a robot, the time granularity is desired to be on the order of at most 100 msec, preferably 10 msec. This is because a robot is required to move more quickly and accurately than a pedestrian. In the real world, the higher the motion speed required of a robot, the shorter the time interval required for establishing the control itself. This is also true for simulation, and it is impossible to perform required simulation of the motion of a robot without decreasing the time granularity according to the required motion speed.

In the example shown in FIG. 1, the time granularity of the robot agents A and B in the virtual world 2 is set to 20 msec, and the time granularity of the pedestrian agent C is set to 100 msec. Each agent simulator A, B, C executes simulations with a control cycle according to the time granularity of the agent A, B, C that each agent simulator A, B, C is in charge of. Although the time granularity of the two robot agents A, B shown in FIG. 1 is the same, even if the agent of the same type, there may be a case where the time granularity is different depending on the purpose.

In the MAS system 100, simulation is performed by the exchange of movement messages between the agent simulators 200. However, the exchange of movement messages for simulation does not occur directly between the agent simulators 200. The MAS system 100 includes a center controller 300 that communicates with the agent simulators 200. Movement messages are relayed by the center controller 300 and exchanged between the agent simulators 200.

In the example shown in FIG. 1, the movement messages output from the agent simulator A are received by the center controller 300. The center controller 300 transmits the movement messages of the agent simulator A to the agent simulators B, C. Similarly, the movement messages of the agent simulator B are transmitted to the agent simulators A, C by the center controller 300, and the movement messages of the agent simulator C are transmitted to the agent simulators A, B by the center controller 300.

### 1-2. Overview of Exchange of Movement Messages in MAS System

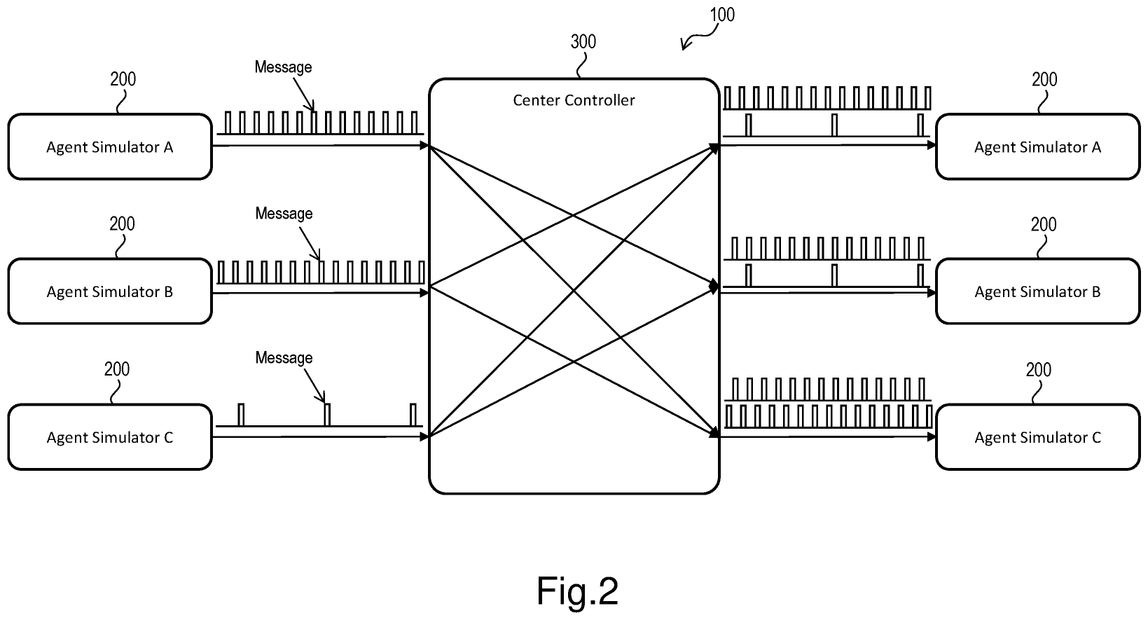

FIG. 2 shows an overview of the exchange of movement messages performed in the MAS system 100. In the MAS system 100, each agent simulator 200 transmits movement messages at a time interval corresponding to the time granularity of the agent to be simulated, rather than at the same time interval between the agent simulators 200. Assuming that the time granularity of each agent A, B, C is as shown in FIG. 1, the agent simulators A, B transmit movement messages at a time interval of 20 msec, and the agent simulator C transmits movement messages at a time interval of 100 msec.

The center controller 300, which receives movement messages from each agent simulator A, B, C, broadcasts the movement messages at the same time interval as the time interval at which the movement messages are received. Thus, to the agent simulator A, as well as movement messages from the agent simulator B are transmitted at a time interval of 20 msec, movement messages from the agent simulator C are transmitted at a time interval of 100 msec. Similarly, to the agent simulator B, as well as movement messages from the agent simulator A are transmitted at a time interval of 20 msec, and movement messages from the agent simulator C are transmitted at a time interval of 100 msec. Further, to the agent simulator C, movement messages from the agent simulators A, B are transmitted at a time interval of 20 msec.

As described above, in the MAS system 100, each agent simulator 200 transmits movement messages at a transmission time interval corresponding to the time granularity of the agent to be simulated, rather than at the same transmission time interval between the agent simulators 200. This reduces the increase in the amount of messages exchanged between the agent simulators 200 while maintaining the performance of the MAS. Further, since the center controller 300 transmits movement messages at the same time interval as the time interval at which the movement messages are received, it is possible to prevent an old movement message from reaching the destination agent simulator 200 before a new movement message. Further, the use of the broadcast as a method of transmitting movement messages by the center controller 300 reduces the load on the center controller 300.

In the real world, the current state of an entity is determined by the relationship with the current state of other entities interacting with it. Therefore, in order to simulate the current state of the agent in the virtual world 2, information on the current states of interacting surrounding agents is required. However, in the MAS system 100, there is a difference between the agent simulators 200 in the transmission time interval at which the movement messages are transmitted depending on the time granularity of the agent that each agent simulator 200 is in charge of. Further, since the transmission of movement messages is discrete, the timing of the exchange of movement messages may be shifted even between the agent simulators 200 having the same transmission time interval. Further, depending on the processing capacity of the CPU and the network capacity, there may be a time delay in the transmission and reception of movement messages between the agent simulators 200 through the center controller 300.

Therefore, in the MAS system 100, when each agent simulator 200 simulates the current state of the ego-agent that each agent simulator 200 is in charge of, the following processing including first to sixth processes is executed.

In the first process, the agent simulator 200 generates, based on the movement messages transmitted from the center controller 300, the states of surrounding agents at the time of acquisition of the movement messages. In the second process, the agent simulator 200 stores in memory the states of the surrounding agents generated in the first process.

In the third process, the agent simulator 200 estimates the current states of the surrounding agents from the past states of the surrounding agents stored in memory in the second process. For a surrounding agent, if the number of past states of the surrounding agent stored in the memory is two or more, the agent simulator 200 estimates the current state of the surrounding agent by linear extrapolation based on the latest two or more past states of the surrounding agent. For a surrounding agent, if the number of past states of the surrounding agent stored in memory is one, the agent simulator 200 estimates the only past state of the surrounding agent as the current state of the surrounding agent.

In the fourth process, the agent simulator 200 simulates the current state of the ego-agent using the current states of the surrounding agents estimated in the third process. In the fifth process, the agent simulator 200 creates a movement message based on the current state of the ego-agent simulated in the fourth process. In the sixth process, the agent simulator 200 transmits the movement message created in the fifth process to the center controller 300.

In the MAS system 100, such processing is performed by each agent simulator 200. Thus, even if there is a time delay in the transmission and reception of movement messages between the agent simulators 200 through the center controller 300, it is possible to accurately simulate the current state of each agent. Further, even if there is a deviation between the agent simulators 200 in the transmission timing of movement messages, the current state of each agent can be simulated with high accuracy. Moreover, even if there is a difference between the agent simulators 200 in the transmission time interval at which movement messages are transmitted depending on the time granularity of each agent, the current state of each agent can be simulated with high accuracy.

### 1-3. Details of Exchange of Movement Messages in MAS System

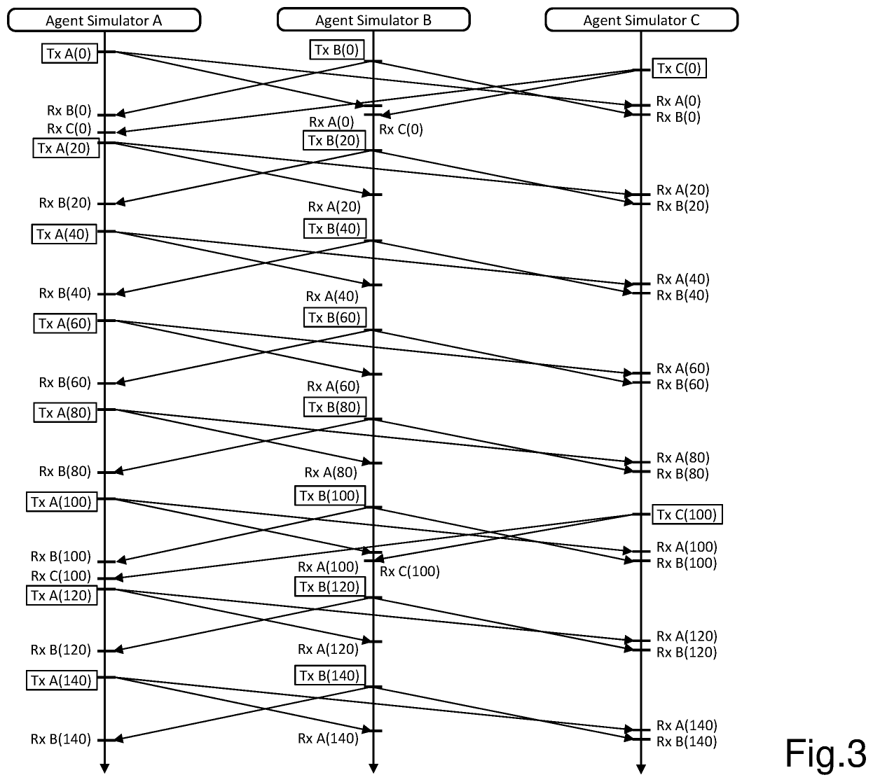

FIG. 3 shows the details of the exchange of movement messages between agent simulators A, B, C performed in the MAS system 100. However, for simplicity, the center controller 300 for relaying the transmission and reception of movement messages between the agent simulator A, B, C is omitted. Assuming that the time granularity of each agent A, B, C is as shown in FIG. 1, the agent simulators A, B transmit movement messages at a time interval of 20 msec, and the agent simulator C transmits movement messages at a time interval of 100 msec.

Here, a time delay of 12 msec is acknowledged between the agent simulator A and the agent simulator B. A time delay of 14 msec is acknowledged between the agent simulator A and the agent simulator C. Then, a time delay of 10 msec is acknowledged between the agent simulator B and the agent simulator C.

Each agent simulator A, B, C begins to simulate at time t=0. However, the times of the internal clocks of the computers acting as the agent simulators A, B, C do not necessarily coincide with one another. For this reason, there may be deviations in the starting time of the simulation between the agent simulators A, B, C. In the MAS system 100, movement messages are exchanged between agent simulators A, B, C on the premise of the difference of the simulation start time.

In FIG. 3, A(t) is a movement message representing the state of the agent A at time t. B(t) is a movement message representing the state of the agent B at time t. C(t) is a movement message representing the state of the agent C at time t. The processes by the agent simulators A, B, C will be described in time series below.

First, movement messages A(0), B(0), C(0) representing the initial state of each agent A, B, C are transmitted from each agent simulator A, B, C. In the initial state, since the agent simulators A, B, C cannot recognize the presence of surrounding agents, they generate the movement messages A(0), B(0), C(0) under the assumption that surrounding agents do not exist.

The next transmission time of the agent simulator A is time t=20. The agent simulator A receives the movement messages B(0), C(0) before time t=20. The agent simulator A recognizes the state of the agent B at time t=0 from the movement message B(0), and estimates the state of the agent B at time t=0 as the current state of the agent B. The agent simulator A recognizes the state of the agent C at time t=0 from the movement message C(0), and estimates the state of the agent C at time t=0 as the current state of the agent C. The agent simulator A generates the state of the agent A at time t=20 by the simulation using the estimated states of the agents B, C, and transmits a movement message A(20) to the agent simulators B, C.

The next transmission time of the agent simulator A is time t=40. The agent simulator A receives a new movement message B(20) from the agent simulator B before time t=40. The agent simulator A recognizes the state of the agent B at time t=20 from the movement message B(20), and estimates the current state of the agent B by linear extrapolation based on the states of the agent B at time t=0 and time t=20. The agent simulator A estimates the state of the agent C at time t=0 as the current state of the agent C. The agent simulator A generates the state of the agent A at time t=40 by the simulation using the estimated states of the agents B, C, and transmits a movement message A(40) to the agent simulators B, C.

The next transmission time of the agent simulator A is time t=60. The agent simulator A receives a new movement message B(40) from the agent simulator B before time t=60, but no new movement message C is received from the agent simulator C. Therefore, the agent simulator A estimates the current state of the agent B by linear extrapolation based on the states of the agent B at time t=20 and time t=40, while estimating the state of the agent C at time t=0 as the current state of the agent C. The agent simulator A generates the state of the agent A at time t=60 by the simulation using the estimated states of the agents B, C, and transmits a movement message A(60) to the agent simulators B, C.

The next transmission time of the agent simulator A is time t=80. The agent simulator A receives a new movement message B(60) from the agent simulator B before time t=80, but no new movement message C is received from the agent simulator C. For this reason, the agent simulator A estimates the current state of the agent B by linear extrapolation based on the states of the agent B at time t=40 and at time t=60, while estimating the state of the agent C at time t=0 as the current state of the agent C. The agent simulator A generates the state of the agent A at time t=80 by the simulation using the estimated states of the agents B, C, and transmits a movement message A(80) to the agent simulators B, C.

The next transmission time of the agent simulator A is time t=100. The agent simulator A receives a new movement message B(80) from the agent simulator B before time t=100, but no new movement message C is received from the agent simulator C. For this reason, the agent simulator A estimates the current state of the agent B by linear extrapolation based on the states of the agent B at time t=60 and at time t=80, while estimating the state of the agent C at time t=0 as the current state of the agent C. The agent simulator A generates the state of the agent A at time t=100 by the simulation using the states of the agent B, C estimated in this way, and transmits a movement message A(100) to the agent simulators B, C.

The next transmission time of the agent simulator A is time t=120. The agent simulator A receives a new movement message B(100) from the agent simulator B before time t=120, and a new movement message C(100) from the agent simulator C. The agent simulator A recognizes the state of the agent B at time t=100 from the movement message B(100), and estimates the current state of the agent B by linear extrapolation based on the state of the agent B at time t=80 and time t=100. The agent simulator A recognizes the state of the agent C at time t=100 from the movement message C(100), and estimates the current state of the agent C by linear extrapolation based on the state of the agent C at time t=0 and time t=100. The agent simulator A generates the state of the agent A at time t=120 by the simulation using the states of the agent B, C estimated in this way, and transmits a movement message A(120) to the agent simulators B, C.

The next transmission time of the agent simulator A is time t=140. The agent simulator A receives a new movement message B(120) from the agent simulator B before time t=140. Therefore, the agent simulator A estimates the current state of the agent B by linear extrapolation based on the state of the agent B at time t=100 and time t=120. On the other hand, no new movement message C has been received from the agent simulator C. Therefore, the agent simulator A estimates the current state of the agent C by linear extrapolation based on the state of the agent C at time t=0 and time t=100. The agent simulator A generates the state of the agent A at time t=140 by the simulation using the states of the agents B, C estimated in this way, and transmits a movement message A(140) to the agent simulators B, C.

The agent simulator B generates the states of the agent B at time t=20, 40, 60, 80, 100, 120, 140 by the same processing as that of the agent simulator A. Then, movement messages B(20), B(40), B(60), B(80), B(100), B(120), B(140) representing the states of respective times are transmitted to the agent simulators A, C.

The next transmission time of the agent simulator C is time t=100. The agent simulator C receives movement messages A(0), A(20), A(40), A(60), A(80) from the agent simulator A before time t=100. The agent simulator C estimates the current state of the agent A by linear extrapolation based on the states of the agent A at time t=60 and at time t=80, which are the two most recent past states. The agent simulator C receives the movement message B(0), B(20), B(40), B(60), B(80) from the agent simulator B before the time t=100. The agent simulator C estimates the current state of the agent B by linear extrapolation based on the states of the agent B at time t=60 and at time t=80, which are the two most recent past states. The agent simulator C generates the state of the agent C at time t=100 by the simulation using the states of the agents A, B estimated in this way, and transmits a movement message C(100) to the agent simulators A, B.

### 2. Overall Configuration and Information Flow of MAS System

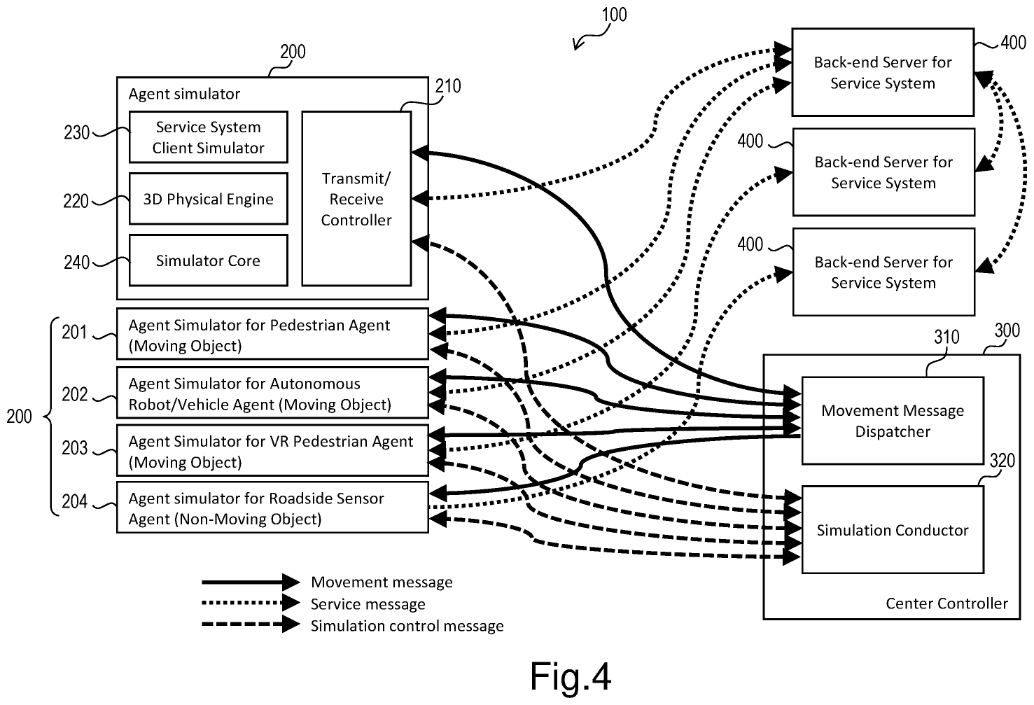

The overall configuration of the MAS system 100 and flows of information will be described below with reference to FIG. 4. As shown in FIG. 4, the MAS system 100 includes a plurality of agent simulators 200, a center controller 300, and a back-end server 400 for a plurality of service systems. As will be described in detail later, these are distributed among a plurality of computers. That is, the MAS system 100 is a system based on parallel distributed processing by a plurality of computers.

The center controller 300 includes, as its function, a movement message dispatcher 310 and a simulation conductor 320. The center controller 300 is application software installed on the computer. The movement message dispatcher 310 and the simulation conductor 320 are programs that comprise the application software. The center controller 300 may share a computer that is hardware with one or more agent simulators 200, but preferably uses one computer exclusively.

The movement message dispatcher 310 relays the transmission and reception of movement messages between the agent simulators 200. Flows of information indicated by solid lines between the agent simulators 200 and the movement message dispatcher 310 indicate flows of movement messages. The movement message dispatcher 310 is responsible for the exchange of the above-described movement messages provided by the center controller 300. The movement message dispatcher 310 communicates with all of the agent simulators 200 comprising the MAS system 100.

The simulation conductor 320 controls the simulation by the agent simulators 200 through the exchange of simulation control messages with the agent simulators 200. Flows of information indicated by dashed lines between the agent simulators 200 and the simulation conductor 320 indicate flows of simulation control messages. The simulation conductor 320 communicates with all of the agent simulators 200 comprising the MAS system 100 to exchange simulation control messages. Unlike movement messages being exchanged between the plurality of agent simulators 200 via the movement message dispatcher 310, simulation control messages are exchanged separately between the simulation conductor 320 and the individual agent simulators 200. The exchange of simulation control messages is used for controlling, for example, simulation speed, stopping the simulation, pausing the simulation, restarting the simulation, and the time granularity of the simulation. The simulation speed is controlled as a whole MAS system 100, whereas stopping the simulation, pausing the simulation, restarting the simulation, and the time granularity of the simulation are controlled for each agent simulator 200.

The back-end server 400 is the same back-end server actually used in the real-world service system. By bringing the back-end server 400 in the real-world into the virtual world, the service provided by the service system can be simulated with high accuracy. The services simulated in the MAS system 100 can include, for example, mobility services such as on-demand buses and ferry type buses using autonomous traveling vehicles, and logistics services for delivering packages using autonomous mobile robots. The service simulated by the MAS system 100 is, for example, a service that can be used by a user operating a service application in a user terminal.

The MAS system 100 includes a plurality of back-end servers 400 for different service systems and can simulate multiple types of services simultaneously in the virtual world 2. The simulation of a service is performed by the exchange of service messages between the back-end server 400 and the agent simulator 200. Flows of information indicated by dotted lines between the agent simulators 200 and the back-end servers 400 indicate flows of service messages. Each back-end server 400 exchanges service messages with the agent simulator 200 related to the provision of the service.

The contents of the service messages exchanged depend on the type of agent that the agent simulator 200 is in charge of. For example, if the agent is a user (a pedestrian) using services, the back-end server 400 receives service messages including service use information from the agent simulator 200 and transmits service messages including service provision state information to the agent simulator 200. The service use information is information on the current state and the future plan on the utilization of the service system by the user, and includes a current use state and input information by an application operation. The service provision state information is information on the state of the user in the service system and is information provided through a service application of the user terminal.

If the agent is an autonomous robot or autonomous vehicle used to provide services, the back-end server 400 receives service messages including operation state information from the agent simulator 200 and transmits service messages including operation instruction information to the agent simulator 200. The operation state information is information on the current state and the future plan of an autonomous robot or autonomous vehicle. The information on the current state is, for example, status of mounted sensors, measured data, status of mounted actuators, and status on action determination. The information on the future plan is, for example, a list of future times, status of actuators, and status of action decisions. The operation instruction information is information that includes all or some of the future plan for providing services using an autonomous robot or autonomous vehicle. For example, the target points and paths that an autonomous robot or autonomous vehicle should move are included in the operation instruction information.

The agents present in the virtual world 2 include non-moving objects such as roadside sensors including cameras and automatic doors. For example, if the agent is a fixed camera, the back-end server 400 receives service messages from the agent simulator 200 containing image information of the fixed camera necessary to calculate location information of the autonomous robot. Also, if the agent is an automatic door, the back-end server 400 transmits service messages to the agent simulator 200 that includes an instruction to open the door for the passage of the autonomous robot.

The back-end server 400 exchanges service messages with the other back-end servers 400 under their respective agreements. Flows of information indicated by dashed lines between the back-end servers 400 indicate flows of service messages. The service messages exchanged at this time includes, for example, the use state of the user in each service and the provision state of the service. By exchanging service messages between the plurality of back-end servers 400, the services provided in the virtual world 2 can be linked to each other.

One example of linkage of a plurality of services is linkage between an on-demand bus service and a logistics service in which autonomous robots carry packages on behalf of users from bus stops to homes. In the on-demand bus service, a user can get off the bus at a desired time and at a desired location. By linking the on-demand bus service and the logistics service, it is possible to have the autonomous robot arrive at the getting-off location before the user arrives and allow the autonomous robot to wait for the user to arrive at the getting-off location. In addition, when the bus is delayed due to traffic congestion or the like, or when the user is delayed on the bus, by exchanging service messages between the back-end servers 400, the time for directing the autonomous robot to the getting-off location can be adjusted to the user's arrival time.

There are a plurality of types of agent simulators 200 according to the types of agents that they are in charge of. For example, there are an agent simulator 201 for a pedestrian agent, an agent simulator 202 for an autonomous robot/vehicle agent, an agent simulator 203 for a VR pedestrian agent, and an agent simulator 204 for a roadside sensor agent. Hereafter, the agent simulator 200 is a general term for the plurality of types of agent simulators 201, 202, 203, 204.

The agent simulator 200 includes, as its function, a transmit/receive controller 210, a 3D physical engine 220, a service system client simulator 230, and a simulator core 240. The agent simulator 200 is application software installed on the computer. The transmit/receive controller 210, the 3D physical engine 220, the service system client simulator 230, and the simulator core 240 are programs that comprise the application software. These functions differ among the agent simulators 201, 202, 203, 204. Here, the functions that are generally common among the agent simulators 201, 202, 203, 204 will be described, and details of the functions of the agent simulators 201, 202, 203, 204 will be described later.

The transmit/receive controller 210 is an interface between the agent simulator 200 and other programs. The transmit/receive controller 210 receives movement messages from the movement message dispatcher 310 and transmits movement messages to the movement message dispatcher 310. However, in the agent simulator 204, only the reception of movement messages is performed. The transmit/receive controller 210 receives simulation control messages from the simulation conductor 320 and transmits simulation control messages to the simulation conductor 320. The transmit/receive controller 210 receives service messages from the back-end server 400 and transmits service messages to the back-end server 400. However, in the agent simulator 204, only the transmission of service messages is performed.

The 3D physical engine 220 estimates the current states of surrounding agents in three-dimensional space based on the movement messages received from other agent simulators 200. Estimation of the current state based on the previous states of the surrounding agents as described with reference to FIG. 3 is performed by the 3D physical engine 220. The 3D physical engine 220 generates peripheral information obtained by observation from the ego-agent based on the current states of the surrounding agents. The 3D physical engine 220 updates the state of the ego-agent in the three-dimensional space based on the simulation result by the simulator core 240 described later, and generates movement messages representing the state of the ego-agent. However, in the agent simulator 204, since the agent that the agent simulator 204 is in charge of is fixed, the state of the ego-agent is not updated and movement messages are not generated.

The service system client simulator 230 simulates the behavior of the ego-agent as a client of the service system associated with the back-end server 400. The service messages received by the transmit/receive controller 210 are input to the service system client simulator 230. The service messages generated by the service system client simulator 230 are transmitted from the transmit/receive controller 210. However, in the agent simulator 204, only the generation of service messages is performed.

The simulator core 240 simulates the state of the ego-agent in the next time step. The time interval of the time step for calculating the state of the ego-agent is the above-mentioned time granularity. The content of the simulation in the simulator core 240 differs for each type of agent simulator 200. Note that the agent simulator 204 does not have the simulator core 240 because the agent that the agent simulator 204 is in charge of is fixed and the simulation of the state of the ego-agent is unnecessary.

### 3. Detailed Configuration and Information Flow of Agent Simulator

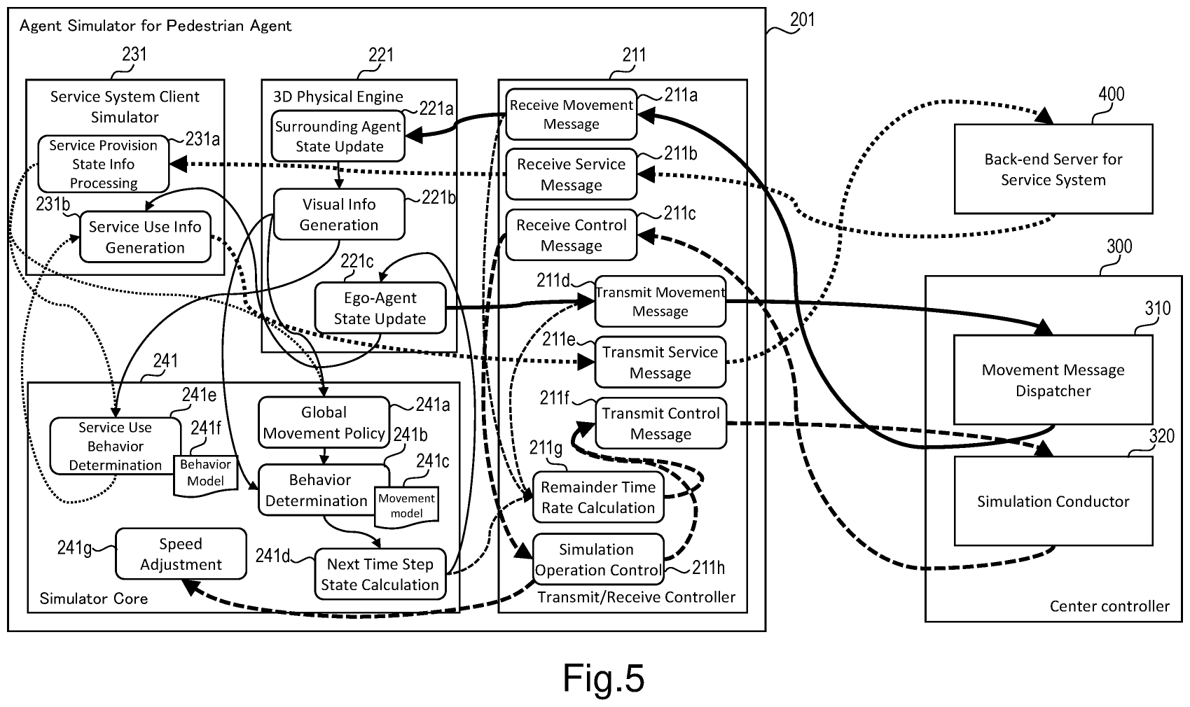

Next, a detailed configuration and information flows of the various agent simulators 201, 202, 203, 204 comprising the MAS system 100 will be described with reference to FIGS. 5 to 8. In FIGS. 5 to 8, flows of information between blocks indicated by solid lines indicate flows of movement messages. Flows of information between blocks indicated by dotted lines indicate flows of service messages. Flows of information between blocks indicated by dashed lines indicate flows of simulation control messages.

### 3-1. Agent Simulator for Pedestrian Agent

FIG. 5 is a block diagram illustrating a configuration and flows of information of an agent simulator 201 for a pedestrian agent. Hereinafter, the overall configuration of the agent simulator 201 for the pedestrian agent, the details of each part, and flows of information in the agent simulator 201 will be described below.

### 3-1-1. Overall Configuration of Agent Simulator for Pedestrian Agent

The agent simulator 201 includes, as its function, a transmit/receive controller 211, a 3D physical engine 221, a service system client simulator 231, and a simulator core 241. These functions are conceptually included in the transmit/receive controller 210, the 3D physical engine 220, the service system client simulator 230, and the simulator core 240, respectively.

The transmit/receive controller 211 includes a movement message receiving unit 211a, a service message receiving unit 211b, and a control message receiving unit 211c as functions for receiving various messages. The transmit/receive controller 211 includes a movement message transmitting unit 211d, a service message transmitting unit 211e, and a control message transmitting unit 211f as functions for transmitting various messages. The transmit/receive controller 211 further includes a remainder time rate calculating unit 211g and a simulation operation controlling unit 211h. Each of the units 211a to 211h comprising the transmit/receive controller 211 is a program or a part of a program. It should be noted that the description in each block describes a representative function of each unit and does not necessarily coincide with the name of each unit.

The 3D physical engine 221 includes, as its functions, a surrounding agent state updating unit 221a, a visual information generating unit 221b, and an ego-agent state updating unit 221c. Each of the units 221a, 221b, 221c comprising the 3D physical engine 221 is a program or a part of a program. It should be noted that the description in each block describes a representative function of each unit and does not necessarily coincide with the name of each unit.

The service system client simulator 231 includes, as its functions, a service provision state information processing unit 231a and a service use information generating unit 231b. Each of the units 231a and 231b comprising the service system client simulator 231 is a program or a part of a program. It should be noted that the description in each block describes a representative function of each unit and does not necessarily coincide with the name of each unit.

The simulator core 241 includes, as its functions, a global movement policy determining unit 241a, a behavior determining unit 241b, a next time step state calculating unit 241d, a service use behavior determining unit 241e, and a speed adjusting unit 241g. Each of the units 241a, 241b, 241d, 241e, 241g comprising the simulator core 241 is a program or a part of a program. It should be noted that the description in each block describes a representative function of each unit and does not necessarily coincide with the name of each unit.

### 3-1-2. Details of Transmit/Receive Controller

In the transmit/receive controller 211, the movement message receiving unit 211a receives a movement message from the movement message dispatcher 310. The movement message receiving unit 211a outputs the received movement message to the surrounding agent state updating unit 221a of the 3D physical engine 221. In addition, the movement message receiving unit 211a outputs information including the time at which the movement message is received to the remainder time rate calculating unit 211g.

The service message receiving unit 211b receives a service message from the back-end server 400. The service message receiving unit 211b outputs the received service message to the service provision state information processing unit 231a of the service system client simulator 231.

The control message receiving unit 211c receives a simulation control message from the simulation conductor 320. The control message receiving unit 211c outputs the received simulation control message to the simulation operation controlling unit 211h.

The movement message transmitting unit 211d acquires a movement message including the current state of the ego-agent from the ego-agent state updating unit 221c of the 3D physical engine 221. The movement message transmitting unit 211d transmits the acquired movement message to the movement message dispatcher 310. In addition, the movement message transmitting unit 211d transmits information including the transmission completion time of the movement message to the remainder time rate calculating unit 211g.

The service message transmitting unit 211e acquires a service message including service use information from the service use information generating unit 231b of the service system client simulator 231. The service message transmitting unit 211e transmits the acquired service message to the back-end server 400.

The control message transmitting unit 211f acquires a simulation control message including information on the speed state of the simulation from the remainder time rate calculating unit 211g. Also, the control message transmitting unit 211f acquires a simulation control message including the control state of the agent simulator 201 from the simulation operation controlling unit 211h. The control message transmitting unit 211f transmits the simulation control messages acquired from the remainder time rate calculating unit 211g and the simulation operation controlling unit 211h to the simulation conductor 320.

The remainder time rate calculating unit 211g acquires information including the reception time of the movement message from the movement message receiving unit 211a. In addition, the remainder time rate calculating unit 211g acquires information including the transmission completion time of the movement message from the movement message transmitting unit 211d. Further, the remainder time rate calculating unit 211g acquires the start time of calculation for updating the state of the ego-agent from the next time step state calculating unit 241d of the simulator core 241.

Here, Ta(N) is the start time of the calculation for updating the state of the ego-agent at this time step. Ta(N+1) is the start time of the calculation for updating the state of the ego-agent at the next time step. Te_last(N) is the reception time of the last received movement message among the movement messages of other agents necessary for the calculation to update the state of the ego-agent at the next time step. Te_first(N+1) is the reception time of the first received movement message among the movement messages of other agents necessary for the calculation to update the state of the ego-agent at the time step after the next time step. Td(N) is the transmission completion time of the movement message at the current time step.

The remainder time rate calculating unit 211g calculates a remainder time, a remainder time rate, and a delay time by the following equations.

Remainder time=Ta(N+1)−Te_last(N)

Remainder time rate=(Ta(N+1)−Te_last(N))/(Ta(N+1)−Ta(N))

Delay time=Td(N)−Te_first(N+1)

The remainder time rate calculating unit 211g outputs a simulation control message including the remainder time, the remainder time rate, and the delay time to the control message transmitting unit 211f. The remainder time, the remainder time rate, and the delay time are information on the speed state of the simulation. The simulation conductor 320, which has received the simulation control message including the above information, determines control contents to be instructed to the agent simulator 201. The control contents to be instructed to the agent simulator 201 is, for example, simulation speed, stopping the simulation, pausing the simulation, and restarting the simulation. The simulation conductor 320 creates a simulation control message that includes the control contents to be instructed and transmits it to the agent simulator 201.

The simulation operation controlling unit 211h acquires a simulation control message from the control message receiving unit 211c. The simulation operation controlling unit 211h controls the simulation operation of the agent simulator 201 in accordance with an instruction included in the simulation control message. For example, when the change of the time granularity of the simulation is instructed, the simulation operation controlling unit 211h changes the time granularity of the simulation by the agent simulator 201 from the initial value to the instructed time granularity. The initial value of the time granularity is stored as a set value in the agent simulator 201. The upper and lower limit values of the time granularity are stored in the simulation conductor 320 for each type of agent.

When the instruction content of the simulation control message is the simulation speed, the simulation operation controlling unit 211h accelerates or decelerates the simulation speed by changing the operating frequency of the 3D physical engine 221 and the simulator cores 241. For example, for the simulator core 241, the instructed simulation speed is output to the speed adjusting unit 241g of the simulator core 241. The simulation speed means a speed ratio of the flow of time in the virtual world 2 to the flow of time in the real world. When the stop of the simulation is instructed, the simulation operation controlling unit 211h stops the simulation by the agent simulator 201. When the stop of the simulation is instructed, the simulation operation controlling unit 211h stops the simulation. When the restart of the simulation is instructed, the simulation operation controlling unit 211h restarts the simulation. The simulation operation controlling unit 211h outputs a simulation control message including the current control state of the agent simulator 201 to the control message transmitting unit 211f.

### 3-1-3. Details of 3D Physical Engine

In the 3D physical engine 221, the surrounding agent state updating unit 221a acquires a movement message from the movement message receiving unit 211a. The movement message acquired from the movement message receiving unit 211a is a movement message transmitted from another agent simulator via the movement message dispatcher 310. The surrounding agent state updating unit 221a estimates the current state of a surrounding agent existing around the ego-agent based on the acquired movement message.

When the current state of the surrounding agent is estimated from the past state, the surrounding agent state updating unit 221a uses the past state of the surrounding agent stored in the log. The method of estimating the current state using the past state of the surrounding agent is described using FIG. 3. The surrounding agent state updating unit 221a outputs the estimated current state of the surrounding agent to the visual information generating unit 221b and updates the log.

The visual information generating unit 221b acquires the current state of the surrounding agent from the surrounding agent state updating unit 221a. The visual information generating unit 221b generates peripheral information obtained by observation from the ego-agent based on the current state of the surrounding agent. Since the ego-agent is a pedestrian, peripheral information obtained by observation means visual information captured by the pedestrian's eyes. The visual information generating unit 221b outputs the generated visual information to the global movement policy determining unit 241a, the behavior determining unit 241b, and the service use behavior determining unit 241e of the simulator core 241.

The ego-agent state updating unit 221c acquires the state of the ego-agent in the next time step simulated by the simulator core 241 from the next time step state calculating unit 241d of the simulator core 241. The ego-agent state updating unit 221c updates the state of the ego-agent in the three-dimensional space based on the simulation result by the simulator core 241. The ego-agent state updating unit 221c outputs a movement message including the updated state of the ego-agent to the movement message transmitting unit 211d of the transmit/receive controller 211. The state of the ego-agent included in the movement message includes the location, direction, speed, acceleration in the current time step, and the location, direction, speed, and acceleration in the next time step. In addition, the ego-agent state updating unit 221c outputs information on the updated state of the ego-agent to the service use information generating unit 231b of the service system client simulator 231.

### 3-1-4. Details of Service System Client Simulator

In the service system client simulator 231, the service provision state information processing unit 231a acquires a service message from the service message receiving unit 211b. The service message acquired from the service message receiving unit 211b includes service provision state information. The service provision state information processing unit 231a processes the service provision state information, and acquires information on the state of the ego-agent as a user of the service system and input items to the service application of the user terminal. The information on the state of the ego-agent as a user is information presented to the user terminal, and the input items are information requested to input in order for the ego-agent to use the service. The service provision state information processing unit 231a outputs the information on the state of the ego-agent as a user and the input items to the service application of the user terminal to the global movement policy determining unit 241a and the service use behavior determining unit 241e of the simulator core 241.

The service use information generating unit 231b acquires the determination result of the service use behavior of the ego-agent from the service use behavior determining unit 241e of the simulator core 241. In addition, the service use information generating unit 231b acquires the state of the ego-agent in the three-dimensional space from the ego-agent state updating unit 221c of the 3D physical engine 221. The service use information generating unit 231b generates service use information based on the acquired information and updates the use state of the service of the ego-agent. The service use information generating unit 231b outputs a service message including the service use information to the service message transmitting unit 211e of the transmit/receive controller 211.

### 3-1-5. Details of Simulator Core

In the simulator core 241, the global movement policy determining unit 241a acquires visual information from the visual information generating unit 221b of the 3D physical engine 221. In addition, the global movement policy determining unit 241a acquires the information on the state of the ego-agent as a user and the input items to the service application of the user terminal from the service provision state information processing unit 231a of the service system client simulator 231. The global movement policy determining unit 241a determines a global movement policy of the ego-agent in the virtual world 2 based on the acquired information. The global movement policy determining unit 241a outputs the determined global movement policy to the behavior determining unit 241b.

The behavior determining unit 241b acquires the global movement policy from the global movement policy determining unit 241a, and acquires visual information from the visual information generating unit 221b of the 3D physical engine 221. The behavior determining unit 241b determines the behavior of the ego-agent by inputting the global movement policy and the visual information to a movement model 241c. The movement model 241c is a simulation model modeling how a pedestrian moves in accordance with surrounding conditions appearing in the eyes of the pedestrian under a certain movement policy. The behavior determining unit 241b outputs the determined behavior of the ego-agent to the next time step state calculating unit 241d.

The next time step state calculating unit 241d acquires the behavior of the ego-agent determined by the behavior determining unit 241b. The next time step state calculating unit 241d calculates the state of the ego-agent in the next time step based on the behavior of the ego-agent. The calculated state of the ego-agent includes the location, direction, speed, and acceleration of the ego-agent in the next time step. The next time step state calculating unit 241d outputs the calculated state of the ego-agent in the next time step to the ego-agent state updating unit 221c of the 3D physical engine 221. The next time step state calculating unit 241d outputs the start time of calculation for updating the state of the ego-agent to the remainder time rate calculating unit 211g of the transmit/receive controller 211.

The service use behavior determining unit 241e acquires the visual information from the visual information generating unit 221b of the 3D physical engine 221. In addition, the service use behavior determining unit 241e acquires the information on the state of the ego-agent as a user and the input items to the service application of the user terminal from the service provision state information processing unit 231a of the service system client simulator 231. The service use behavior determining unit 241e inputs the acquired information to a behavior model 241f to determine the behavior of the ego-agent as a user of the service system (service use behavior). The behavior model 241f is a simulation model that models how a user behaves in accordance with surrounding conditions appearing in the eyes of the user when information on the service is presented to the user and input to the service application of the user terminal is requested. The service use behavior determining unit 241e outputs the determined service use behavior to the service use information generating unit 231b.

The speed adjusting unit 241g acquires the simulation speed from the simulation operation controlling unit 211h. The simulation speed acquired from the simulation operation controlling unit 211h is the simulation speed instructed by the simulation conductor 320. The speed adjusting unit 241g accelerates or decelerates the simulation speed of the ego-agent by the simulator core 241 in accordance with an instruction from the simulation conductor 320.

### 3-2. Agent Simulator for Autonomous Robot/Vehicle Agent

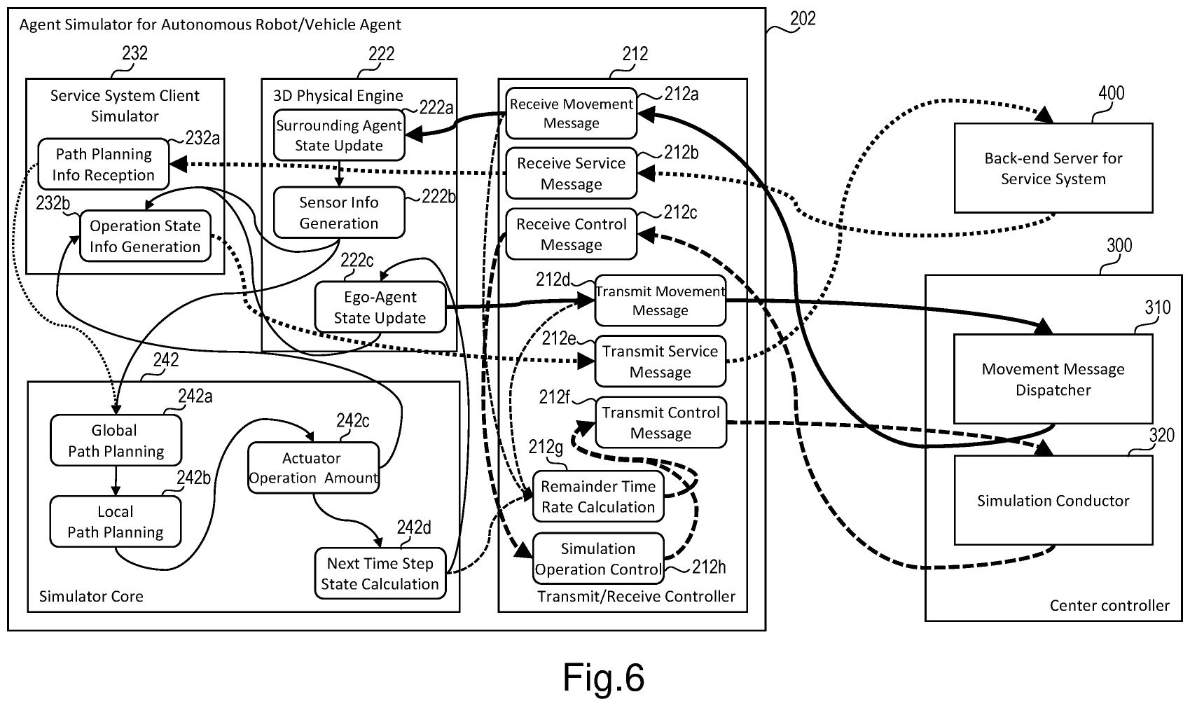

FIG. 6 is a block diagram illustrating a configuration and flows of information of an agent simulator 202 for an autonomous robot/vehicle agent. The autonomous robot/vehicle agent is an agent for autonomous robot or autonomous vehicle used to provide services in the service system to which the back-end server 400 relates. Hereinafter, the overall configuration of the agent simulator 202 for the autonomous robot/vehicle agent, the details of each part, and flows of information in the agent simulator 202 will be described below.

### 3-2-1. Overall Configuration of Agent Simulator for Autonomous Robot/Vehicle Agent

The agent simulator 202 includes, as its function, a transmit/receive controller 212, a 3D physical engine 222, a service system client simulator 232, and a simulator core 242. These functions are conceptually included in the transmit/receive controller 210, the 3D physical engine 220, the service system client simulator 230, and the simulator core 240, respectively.

The transmit/receive controller 212 includes a movement message receiving unit 212a, a service message receiving unit 212b, and a control message receiving unit 212c as functions for receiving various messages. The transmit/receive controller 212 includes a movement message transmitting unit 212d, a service message transmitting unit 212e, and a control message transmitting unit 212f as functions for transmitting various messages. The transmit/receive controller 212 further includes a remainder time rate calculating unit 212g and a simulation operation controlling unit 212h. Each of the units 212a to 212h comprising the transmit/receive controller 211 is a program or a part of a program. It should be noted that the description in each block describes a representative function of each unit and does not necessarily coincide with the name of each unit.

The 3D physical engine 222 includes, as its functions, a surrounding agent state updating unit 222a, a sensor information generating unit 222b, and an ego-agent state updating unit 222c. Each of the units 222a, 222b, 222c comprising the 3D physical engine 222 is a program or a part of a program. It should be noted that the description in each block describes a representative function of each unit and does not necessarily coincide with the name of each unit.

The service system client simulator 232 includes, as its functions, a path planning information receiving unit 232a and an operation state information generating unit 232b. Each of the units 232a and 232b comprising the service system client simulator 232 is a program or a part of a program. It should be noted that the description in each block describes a representative function of each unit and does not necessarily coincide with the name of each unit.

The simulator core 242 includes, as its functions, a global path planning unit 242a, a local path planning unit 242b, an actuator operation amount determining unit 242c, and a next time step state calculating unit 242d. Each of the units 242a, 242b, 242c, 242d comprising the simulator core 242 is a program or a part of a program. It should be noted that the description in each block describes a representative function of each unit and does not necessarily coincide with the name of each unit.

### 3-2-2. Details of Transmit/Receive Controller

In the transmit/receive controller 212, the movement message receiving unit 212a receives a movement message from the movement message dispatcher 310. The movement message receiving unit 212a outputs the received movement message to the surrounding agent state updating unit 222a of the 3D physical engine 222. In addition, the movement message receiving unit 212a outputs information including the time at which the movement message is received to the remainder time rate calculating unit 212g.

The service message receiving unit 212b receives a service message from the back-end server 400. The service message receiving unit 212b outputs the received service message to the path planning information receiving unit 232a of the service system client simulator 232.

The control message receiving unit 212c receives a simulation control message from the simulation conductor 320. The control message receiving unit 212c outputs the received simulation control message to the simulation operation controlling unit 212h.

The movement message transmitting unit 212d acquires a movement message including the current state of the ego-agent from the ego-agent state updating unit 222c of the 3D physical engine 222. The movement message transmitting unit 212d transmits the acquired movement message to the movement message dispatcher 310. In addition, the movement message transmitting unit 212d transmits information including the transmission completion time of the movement message to the remainder time rate calculating unit 212g.

The service message transmitting unit 212e acquires a service message including operation state information from the operation state information generating unit 232b of the service system client simulator 232. The service message transmitting unit 212e transmits the acquired service message to the back-end server 400.

The control message transmitting unit 212f acquires a simulation control message including information on the speed state of the simulation from the remainder time rate calculating unit 212g. Also, the control message transmitting unit 212f acquires a simulation control message including the control state of the agent simulator 202 from the simulation operation controlling unit 212h. The control message transmitting unit 212f transmits the simulation control messages acquired from the remainder time rate calculating unit 212g and the simulation operation controlling unit 212h to the simulation conductor 320.

The remainder time rate calculating unit 212g acquires information including the reception time of the movement message from the movement message receiving unit 212a. In addition, the remainder time rate calculating unit 212g acquires information including the transmission completion time of the movement message from the movement message transmitting unit 212d. Further, the remainder time rate calculating unit 212g acquires the start time of calculation for updating the state of the ego-agent from the next time step state calculating unit 242d of the simulator core 242.

The remainder time rate calculating unit 212g calculates the remainder time, the remainder time rate, and the delay time based on the acquired information by the above-described equations. The remainder time rate calculating unit 212g outputs a simulation control message including the remainder time, the remainder time rate, and the delay time to the control message transmitting unit 212f. Upon receiving the simulation control message including the above information, the simulation conductor 320 creates a simulation control message including control contents to be instructed to the agent simulator 202 and transmits the simulation control message to the agent simulator 202.

The simulation operation controlling unit 212h acquires a simulation control message from the control message receiving unit 212c. The simulation operation controlling unit 212h controls the simulation operation of the agent simulator 202 in accordance with an instruction included in the simulation control message. For example, when the change of the time granularity of the simulation is instructed, the simulation operation controlling unit 212h changes the time granularity of the simulation by the agent simulator 202 from the initial value to the instructed time granularity. The initial value of the time granularity is stored as a set value in the agent simulator 202. The upper and lower limit values of the time granularity are stored in the simulation conductor 320 for each type of agent.

When the instruction content of the simulation control message is the simulation speed, the simulation operation controlling unit 212h changes the operating frequency of the 3D physical engine 222 and the simulator cores 242 in accordance with the instructed simulation speed, and accelerates or decelerates the operation speed of the agent simulator 202. When the stop of the simulation is instructed, the simulation operation controlling unit 212h stops the simulation by the agent simulator 202. When the stop of the simulation is instructed, the simulation operation controlling unit 212h stops the simulation. When the restart of the simulation is instructed, the simulation operation controlling unit 212h restarts the simulation. The simulation operation controlling unit 212h outputs a simulation control message including the current control state of the agent simulator 202 to the control message transmitting unit 212f.

### 3-2-3. Details of 3D Physical Engine

In the 3D physical engine 222, the surrounding agent state updating unit 222a acquires a movement message from the movement message receiving unit 212a. The movement message acquired from the movement message receiving unit 212a is a movement message transmitted from another agent simulator via the movement message dispatcher 310. The surrounding agent state updating unit 222a estimates the current state of a surrounding agent existing around the ego-agent based on the acquired movement message.

When the current state of the surrounding agent is estimated from the past state, the surrounding agent state updating unit 222a uses the past state of the surrounding agent stored in the log. The method of estimating the current state using the past state of the surrounding agent is described using FIG. 3. The surrounding agent state updating unit 222a outputs the estimated current state of the surrounding agent to the sensor information generating unit 222b and updates the log.

The sensor information generating unit 222b acquires the current state of the surrounding agent from the surrounding agent state updating unit 222a. The sensor information generating unit 222b generates peripheral information obtained by observation from the ego-agent based on the current state of the surrounding agent. Since the ego-agent is an autonomous robot or an autonomous vehicle, peripheral information obtained by observation means sensor information captured by a sensor mounted on the autonomous robot or the autonomous vehicle. The sensor information generating unit 222b outputs the generated sensor information to the global path planning unit 242a of the simulator core 242 and the operation state information generating unit 232b of the service system client simulator 232.

The ego-agent state updating unit 222c acquires the state of the ego-agent in the next time step calculated by the simulator core 242 from the next time step state calculating unit 242d of the simulator core 242. The ego-agent state updating unit 222c updates the state of the ego-agent in the three-dimensional space based on the calculation result by the simulator core 242. The ego-agent state updating unit 222c outputs a movement message including the updated state of the ego-agent to the movement message transmitting unit 212d of the transmit/receive controller 212. The state of the ego-agent included in the movement message includes the location, direction, speed, acceleration in the current time step, and the location, direction, speed, and acceleration in the next time step. In addition, the ego-agent state updating unit 222c outputs the updated information on the state of the ego-agent to the operation state information generating unit 232b of the service system client simulator 232.

### 3-2-4. Details of Service System Client Simulator

In the service system client simulator 232, the path planning information receiving unit 232a acquires a service message from the service message receiving unit 211b. The service message obtained from the service message receiving unit 212b includes operation instruction information for the service system to provide services using the autonomous robot/vehicle and information related to other service systems. The path planning information receiving unit 232a outputs the operation instruction information and the other service system information to the global path planning unit 242a of the simulator core 242.

The operation state information generating unit 232b acquires the actuator operation amount in the next time step of the ego-agent from the actuator operation amount determining unit 242c of the simulator core 242. Also, the operation state information generating unit 232b acquires the sensor information from the sensor information generating unit 222b of the 3D physical engine 222, and acquires the state of the ego-agent in the three-dimensional space from the ego-agent state updating unit 222c. The operation state information generating unit 232b generates operation state information representing the operation state of the ego-agent related to the provision of the service based on the acquired information. The operation state information generating unit 232b outputs a service message including the operation state information to the service message transmitting unit 212e of the transmit/receive controller 212.

### 3-2-5. Derails of Simulator Core

In the simulator core 242, the global path planning unit 242a acquires sensor information from the sensor information generating unit 222b of the 3D physical engine 222. The global path planning unit 242a acquires the operation instruction information and the other service system information from the path planning information receiving unit 232a of the service system client simulator 232. The global path planning unit 242a plans the global path of the ego-agent in the virtual world 2 based on the acquired information. The global path refers to the path from the current location of the ego-agent to the target point. Since the information acquired from the sensor information generating unit 222b and the path planning information receiving unit 232a changes every time, the global path planning unit 242a determines a global path plan for each time step. The global path planning unit 242a outputs the determined global path plan to the local path planning unit 242b.

The local path planning unit 242b acquires the global path plan from the global path planning unit 242a. The local path planning unit 242b determines a local path plan based on the global path plan. The local path means, for example, a path from the current time point to a time point after a predetermined time step, or a path from the current position to a position separated by a predetermined distance. A local path plan is represented, for example, by a set of locations to be traversed by the ego-agent and a speed or acceleration at each location. The local path planning unit 242b outputs the determined local path plan to the actuator operation amount determining unit 242c.

The actuator operation amount determining unit 242c acquires the local path plan from the local path planning unit 242b. The actuator operation amount determining unit 242c determines actuator operation amounts of the ego-agent in the next time step based on the local path plan. The actuators here include actuators that control the direction, speed, and acceleration of the ego-agent. When the ego-agent is an autonomous robot/vehicle traveling on wheels, for example, actuators such as a braking device, a driving device, and a steering device are operated. The actuator operation amount determining unit 242c outputs the determined actuator operation amounts to the next time step state calculating unit 242d and the operation state information generating unit 232b of the service system client simulator 232.

The next time step state calculating unit 242d acquires the actuator operation amounts determined by the actuator operation amount determining unit 242c. The next time step state calculating unit 242d calculates the state of the ego-agent in the next time step based on the actuator operation amounts. The calculated state of the ego-agent includes the location, direction, speed, and acceleration of the ego-agent in the next time step. The next time step state calculating unit 242d outputs the calculated state of the ego-agent in the next time step to the ego-agent state updating unit 222c of the 3D physical engine 222. The next time step state calculating unit 242d outputs the start time of calculation for updating the state of the ego-agent to the remainder time rate calculating unit 212g of the transmit/receive controller 212.

### 3-3. Agent Simulator for VR Pedestrian Agent

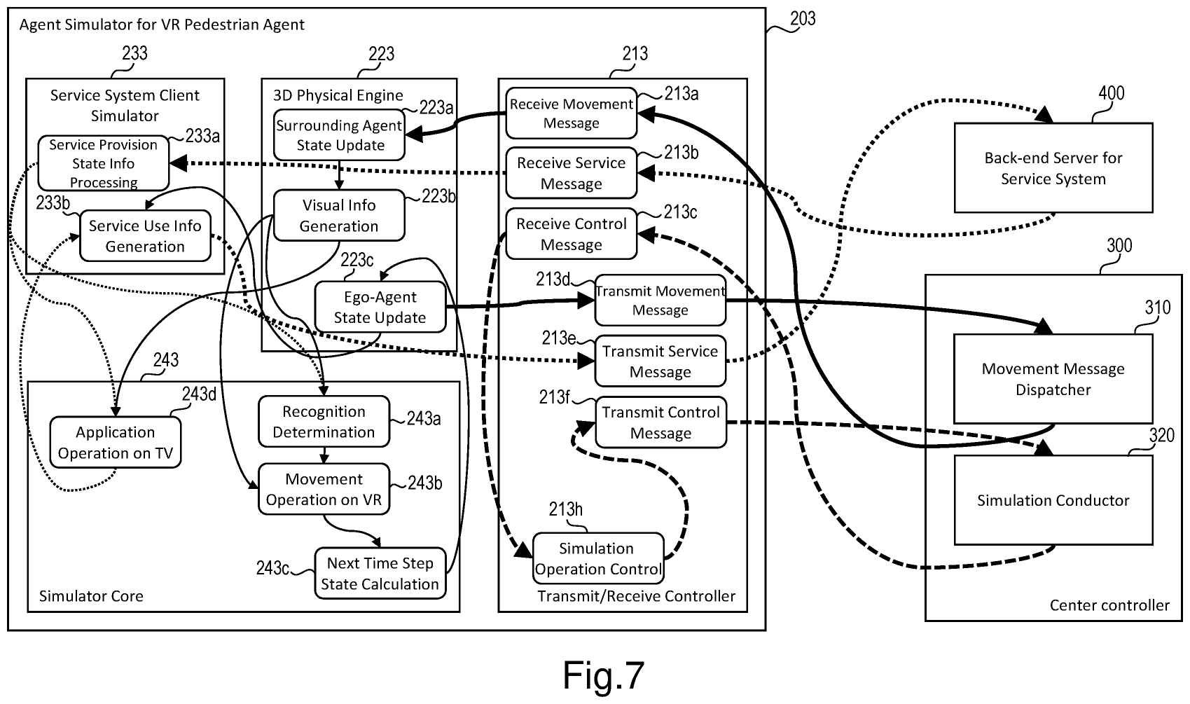

FIG. 7 is a block diagram illustrating a configuration and flows of information of an agent simulator 203 for a VR pedestrian agent. The VR pedestrian agent is a pedestrian agent for a real person to participate in the virtual world 2 which is the target of simulation by using the VR (Virtual Reality) system. Hereinafter, the overall configuration of the agent simulator 203 for the VR pedestrian agent, the details of each part, and flows of information in the agent simulator 203 will be described below.

### 3-3-1. Overall Configuration of Agent Simulator for VR Pedestrian Agent

The agent simulator 203 includes, as its function, a transmit/receive controller 213, a 3D physical engine 223, a service system client simulator 233, and a simulator core 243. These functions are conceptually included in the transmit/receive controller 210, the 3D physical engine 220, the service system client simulator 230, and the simulator core 240, respectively.

The transmit/receive controller 213 includes a movement message receiving unit 213a, a service message receiving unit 213b, and a control message receiving unit 213c as functions for receiving various messages. The transmit/receive controller 213 includes a movement message transmitting unit 213d, a service message transmitting unit 213e, and a control message transmitting unit 213f as functions for transmitting various messages. The transmit/receive controller 213 further includes a simulation operation controlling unit 213h. Each of the units 213a to 213f and 213h comprising the transmit/receive controller 213 is a program or a part of a program. It should be noted that the description in each block describes a representative function of each unit and does not necessarily coincide with the name of each unit.

The 3D physical engine 223 includes, as its functions, a surrounding agent state updating unit 223a, a visual information generating unit 223b, and an ego-agent state updating unit 223c. Each of the units 223a, 223b, 223c comprising the 3D physical engine 223 is a program or a part of a program. It should be noted that the description in each block describes a representative function of each unit and does not necessarily coincide with the name of each unit.

The service system client simulator 233 includes, as its functions, a service provision state information processing unit 233a and a service use information generating unit 233b. Each of the units 233a and 233b comprising the service system client simulator 231 is a program or a part of a program. It should be noted that the description in each block describes a representative function of each unit and does not necessarily coincide with the name of each unit.

The simulator core 243 includes, as its functions, a recognition determination information presenting unit 243a, a movement operation accepting unit 243b, a next time step state calculating unit 243c, and an application operation accepting unit 243 d. Each of the units 243a, 243b, 243c, 243d comprising the simulator core 243 is a program or a part of a program. It should be noted that the description in each block describes a representative function of each unit and does not necessarily coincide with the name of each unit.

### 3-3-2. Details of Transmit/Receive Controller

In the transmit/receive controller 213, the movement message receiving unit 213a receives a movement message from the movement message dispatcher 310. The movement message receiving unit 213a outputs the received movement message to the surrounding agent state updating unit 223a of the 3D physical engine 223.

The service message receiving unit 213b receives a service message from the back-end server 400. The service message receiving unit 213b outputs the received service message to the service provision state information processing unit 233a of the service system client simulator 233.

The control message receiving unit 213c receives a simulation control message from the simulation conductor 320. The control message receiving unit 213c outputs the received simulation control message to the simulation operation controlling unit 213h.

The movement message transmitting unit 213d acquires a movement message including the current state of the ego-agent from the ego-agent state updating unit 223c of the 3D physical engine 223. The movement message transmitting unit 213d transmits the acquired movement message to the movement message dispatcher 310.

The service message transmitting unit 213e acquires a service message including service use information from the service use information generating unit 233b of the service system client simulator 233. The service message transmitting unit 213e transmits the acquired service message to the back-end server 400.

The control message transmitting unit 213f acquires a simulation control message including the control state of the agent simulator 203 from the simulation operation controlling unit 213h. The control message transmitting unit 213f transmits the simulation control message acquired from the simulation operation controlling unit 213h to the simulation conductor 320.

The simulation operation controlling unit 213h acquires a simulation control message from the control message receiving unit 213c. The simulation operation controlling unit 213h controls the simulation operation of the agent simulator 203 in accordance with an instruction included in the simulation control message. When the VR pedestrian agent does not satisfy the participation condition in the virtual world 2, the simulation conductor 320 instructs the agent simulator 203 to stop the simulation.

The agent simulators 201,202 described above and the agent simulator 204 described later can change the simulation speed as needed. However, if the simulation speed is changed, a real-world participant participating in the virtual world 2 through the VR pedestrian agent may feel a strong discomfort against the flow of time different from the real world. Therefore, in the MAS system 100, participation of the VR pedestrian agent to the virtual world 2 is allowed on the condition that the simulation is being performed in real time. When the simulation speed is accelerated or decelerated more than the flow of time in the real world, the simulation conductor 320 stops the simulation by the agent simulator 203. The simulation operation controlling unit 213h outputs a simulation control message including the current control state of the agent simulator 203 to the control message transmitting unit 213f.

### 3-3-3. Details of 3D Physical Engine

In the 3D physical engine 223, the surrounding agent state updating unit 223a acquires a movement message from the movement message receiving unit 213a. The movement message acquired from the movement message receiving unit 213a is a movement message transmitted from another agent simulator via the movement message dispatcher 310. The surrounding agent state updating unit 223a estimates the current state of a surrounding agent existing around the ego-agent based on the acquired movement message.

When the current state of the surrounding agent is estimated from the past state, the surrounding agent state updating unit 223a uses the past state of the surrounding agent stored in the log. The method of estimating the current state using the past state of the surrounding agent is described using FIG. 3. The surrounding agent state updating unit 223a outputs the estimated current state of the surrounding agent to the visual information generating unit 223b and updates the log.

The visual information generating unit 223b acquires the current state of the surrounding agent from the surrounding agent state updating unit 223a. The visual information generating unit 223b generates peripheral information obtained by observation from the ego-agent based on the current state of the surrounding agent. Since the ego-agent is a pedestrian, peripheral information obtained by observation means visual information captured by the pedestrian's eyes. The visual information generating unit 223b outputs the generated visual information to the recognition determination information presenting unit 243a and the movement operation accepting unit 243b of the simulator core 243.

The ego-agent state updating unit 223c acquires the state of the ego-agent in the next time step calculated by the simulator core 243 from the next time step state calculating unit 243c of the simulator core 243. The ego-agent state updating unit 223c updates the state of the ego-agent in the three-dimensional space based on the calculation result by the simulator core 243. The ego-agent state updating unit 223c outputs a movement message including the updated state of the ego-agent to the movement message transmitting unit 213d of the transmit/receive controller 213. The state of the ego-agent included in the movement message includes the location, direction, speed, acceleration in the current time step, and the location, direction, speed, and acceleration in the next time step. In addition, the ego-agent state updating unit 223c outputs information on the updated state of the ego-agent to the service use information generating unit 233b of the service system client simulator 233.

### 3-3-4. Details of Service System Client Simulator

In the service system client simulator 233, the service provision state information processing unit 233a acquires a service message from the service message receiving unit 213b. The service message acquired from the service message receiving unit 213b includes service provision state information. The service provision state information processing unit 233a processes the service provision state information, and acquires information on the state of the ego-agent as a user of the service system and input items to the service application of the user terminal. The information on the state of the ego-agent as a user is information presented to the user terminal, and the input items are information requested to input in order for the ego-agent to use the service. The service provision state information processing unit 233a outputs the information on the state of the ego-agent as a user and the input items to the service application of the user terminal to the recognition determination information presenting unit 243a and the application operation accepting unit 243d of the simulator core 243.

The service use information generating unit 233b acquires the operation of the service application on the VR by a real participant participating in the virtual world 2 via the VR pedestrian agent from the application operation accepting unit 243d of the simulator core 243. In addition, the service use information generating unit 233b acquires the state of the ego-agent in the three-dimensional space from the ego-agent state updating unit 223c of the 3D physical engine 223. The service use information generating unit 233b generates service use information based on the acquired information and updates the use state of the service of the ego-agent. The service use information generating unit 233b outputs a service message including the service use information to the service message transmitting unit 213e of the transmit/receive controller 213.

### 3-3-5. Details of Simulator Core

In the simulator core 243, the recognition determination information presenting unit 243a acquires visual information from the visual information generating unit 223b of the 3D physical engine 223. In addition, the recognition determination information presenting unit 243a acquires the information on the state of the ego-agent as a user and the input items to the service application of the user terminal from the service provision state information processing unit 233a of the service system client simulator 231. The acquired information is information for recognition determination for the real participant participating in the virtual world 2 through the VR pedestrian agent. The recognition determination information presenting unit 243a presents the recognition determination information to the real participant through the VR system.

The movement operation accepting unit 243b acquires visual information from the visual information generating unit 223b of the 3D physical engine 223. The movement operation accepting unit 243b accepts a movement operation on the VR by the real participant while presenting the visual information to the real participant through the VR system. The movement operation accepting unit 243b outputs the accepted movement operation on the VR by the real participant to the next time step state calculating unit 243d.

The next time step state calculating unit 243d acquires the movement operation on the VR by the real participant from the movement operation accepting unit 243b. The next time step state calculating unit 243d calculates the state of the ego-agent in the next time step based on the movement operation on the VR by the real participant. The calculated state of the ego-agent includes the location, direction, speed, and acceleration of the ego-agent in the next time step. The next time step state calculating unit 243d outputs the calculated state of the ego-agent in the next time step to the ego-agent state updating unit 223c of the 3D physical engine 223.

The application operation accepting unit 243d acquires visual information from the visual information generating unit 223b of the 3D physical engine 223. In addition, the application operation accepting unit 243d acquires the information on the state of the ego-agent as a user and the input items to the service application of the user terminal from the service provision state information processing unit 233a of the service system client simulator 233. The application operation accepting unit 243d accepts the operation of the service application on the VR by the real participant while presenting the acquired information to the real participant through the VR system. The application operation accepting unit 243d outputs the accepted operation of the service application on the VR by the real participant to the service use information generating unit 233b of the service system client simulator 233.

### 3-4. Agent Simulator for Roadside Sensor Agent

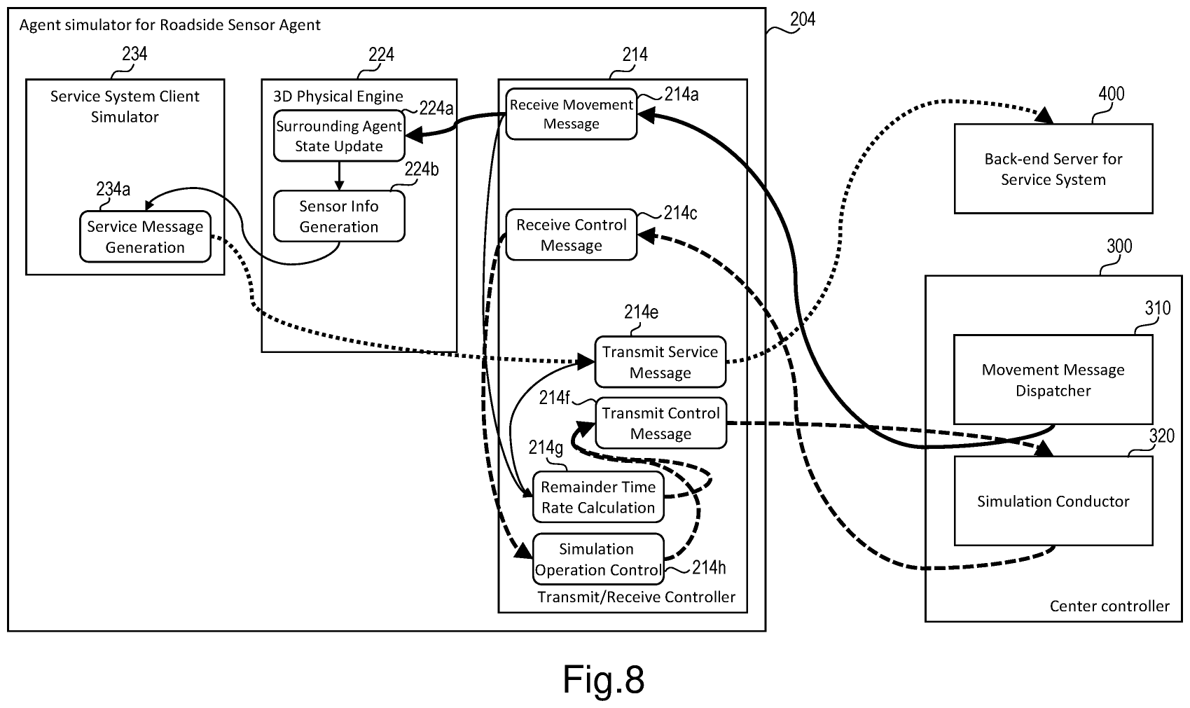

FIG. 8 is a block diagram illustrating the configuration and flows of information of an agent simulator 204 for a roadside sensor agent. The roadside sensor agent is an agent of a roadside sensor used for acquisition of location information of an autonomous robot/vehicle agent in the virtual world 2. The location information of the autonomous robot/vehicle agent acquired by the roadside sensor agent is used in the service system associated with the back-end server 400. Hereinafter, the overall configuration of the agent simulator 204 for the roadside sensor agent, the details of each part, and flows of information in the agent simulator 204 will be described.

### 3-4-1. Overall Configuration of Agent Simulator for Roadside Sensor Agent

The agent simulator 204 includes, as its function, a transmit/receive controller 214, a 3D physical engine 224, and a service system client simulator 234. These functions are conceptually included in the transmit/receive controllers 210, 3D physical engine 220, and the simulator core 240, respectively. The agent simulator 204 does not have a simulator core unlike other agent simulators.

The transmit/receive controller 214 includes a movement message receiving unit 214a and a control message receiving unit 214b as functions for receiving various messages. The transmit/receive controller 214 includes a service message transmitting unit 214e and a control message transmitting unit 214f as functions for transmitting various messages. The transmit/receive controller 214 further includes a remainder time rate calculating unit 214g and a simulation operation controlling unit 214h. Each of the units 214a, 214c and 214e to 214h comprising the transmit/receive controller 214 is a program or a part of a program. It should be noted that the description in each block describes a representative function of each unit and does not necessarily coincide with the name of each unit.

The 3D physical engine 224 includes, as its function, a surrounding agent state updating unit 224a and a sensor information generating unit 224b. Each of the units 224a, 224b comprising the 3D physical engine 224 is a program or a part of a program. It should be noted that the description in each block describes a representative function of each unit and does not necessarily coincide with the name of each unit.

The service system client simulator 234 includes a service message generating unit 234a as a function thereof. The service message generator 234a comprising the service system client simulator 234 is a program or a part of a program. It should be noted that the description in each block describes a representative function of each unit and does not necessarily coincide with the name of each unit.

### 3-4-2. Details of Transmit/Receive Controller

In the transmit/receive controller 214, the movement message receiving unit 214a receives a movement message from the movement message dispatcher 310. The movement message receiving unit 214a outputs the received movement message to the surrounding agent state updating unit 224a of the 3D physical engine 224. In addition, the movement message receiving unit 214a outputs information including the time at which the movement message is received to the remainder time rate calculating unit 214g.

The control message receiving unit 214c receives a simulation control message from the simulation conductor 320. The control message receiving unit 214c outputs the received simulation control message to the simulation operation controlling unit 214h.

The service message transmitting unit 214e acquires a service message including sensor information from the service message generating unit 234a of the service system client simulator 234. The service message transmitting unit 214e transmits the acquired service message to the back-end server 400.

The control message transmitting unit 214f acquires a simulation control message including information on the speed state of the simulation from the remainder time rate calculating unit 214g. Also, the control message transmitting unit 214f acquires a simulation control message including the control state of the agent simulator 204 from the simulation operation controlling unit 214h. The control message transmitting unit 214f transmits the simulation control messages acquired from the remainder time rate calculating unit 214g and the simulation operation controlling unit 214h to the simulation conductor 320.

The remainder time rate calculating unit 214g acquires information including the reception time of the movement message from the movement message receiving unit 214a. The remainder time rate calculating unit 214g acquires information including the transmission completion time of the service message from the service message transmitting unit 214e. The remainder time rate calculating unit 214g calculates the remainder time, the remainder time rate, and the delay time based on the acquired information by the above-described equations. However, in the calculation of the residual time and the residual time rate, the calculated value calculated from the operating frequency of the agent simulator 204 is used for Ta(N+1) and Ta(N). In addition, the transmission completion time of the service message is used in place of the transmission completion time of the movement message in the current time step in Td(N).

The remainder time rate calculating unit 214g outputs a simulation control message including the remainder time, the remainder time rate, and the delay time to the control message transmitting unit 214f. Upon receiving the simulation control message including the above information, the simulation conductor 320 creates a simulation control message including the control contents to be instructed to the agent simulator 204, and transmits the simulation control message to the agent simulator 204.

The simulation operation controlling unit 214h acquires a simulation control message from the control message receiving unit 214c. The simulation operation controlling unit 214h controls the simulation operation of the agent simulator 204 in accordance with an instruction included in the simulation control message. For example, when the change of the time granularity of the simulation is instructed, the simulation operation controlling unit 214h changes the time granularity of the simulation by the agent simulator 204 from the initial value to the instructed time granularity. The initial value of the time granularity is stored as a set value in the agent simulator 204. The upper and lower limit values of the time granularity are stored in the simulation conductor 320 for each type of agent.

When the instruction content of the simulation control message is the simulation speed, the simulation operation controlling unit 214h changes the operating frequency of the 3D physical engine 224 in accordance with the instructed simulation speed, and accelerates or decelerates the operation speed of the agent simulator 204. When the stop of the simulation is instructed, the simulation operation controlling unit 214h stops the simulation by the agent simulator 204. When the stop of the simulation is instructed, the simulation operation controlling unit 214h stops the simulation. When the restart of the simulation is instructed, the simulation operation controlling unit 214h restarts the simulation. The simulation operation controlling unit 214h outputs a simulation control message including the current control state of the agent simulator 204 to the control message transmitting unit 214f.

### 3-4-3. Details of 3D Physical Engine

In the 3D physical engine 224, the surrounding agent state updating unit 224a acquires a movement message from the movement message receiving unit 214a. The movement message acquired from the movement message receiving unit 214a is a movement message transmitted from another agent simulator via the movement message dispatcher 310. The surrounding agent state updating unit 224a estimates the current state of a surrounding agent existing around the ego-agent based on the acquired movement message.

When the current state of the surrounding agent is estimated from the past state, the surrounding agent state updating unit 224a uses the past state of the surrounding agent stored in the log. The method of estimating the current state using the past state of the surrounding agent is described using FIG. 3. The surrounding agent state updating unit 224a outputs the estimated current state of the surrounding agent to the sensor information generating unit 224b and updates the log.

The sensor information generating unit 224b acquires the current state of the surrounding agent from the surrounding agent state updating unit 224a. The sensor information generating unit 224b generates peripheral information obtained by observation from the ego-agent based on the current state of the surrounding agent. Since the ego-agent is a non-moving roadside sensor like a camera, peripheral information obtained by observation means sensor information captured by the roadside sensor. The sensor information generating unit 224b outputs the generated sensor information to the service message generating unit 234a of the service system client simulator 234.

### 3-4-4. Details of Service System Client Simulator

In the service system client simulator 234, the service message generator 234a acquires sensor information from the sensor information generator 224b of the 3D physical engine 224. The service message generating unit 234a outputs a service message including the acquired sensor information to the service message transmitting unit 214e of the transmit/receive controller 214.

### 4. Configuration and Information Flow of Movement Message Dispatcher

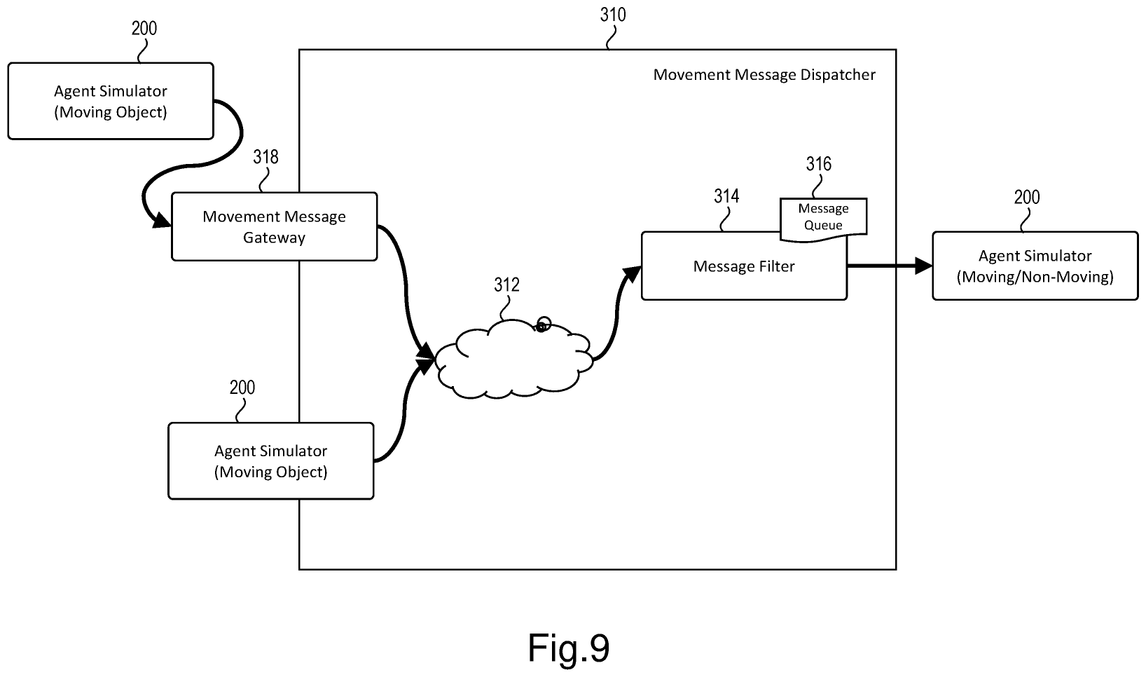

Here, an example of a configuration of the movement message dispatcher 310 for relaying movement messages exchanged between the agent simulators 200 will be described. FIG. 9 is a block diagram illustrating an example of a configuration and flows of information of the movement message dispatcher 310. The movement message dispatcher 310 includes a broadcast distribution network 312, a message filter 314, and a movement message gateway 318. In the MAS system 100, only the agent simulator 200 whose agent is a movement object is the source of the movement message, whereas all agent simulators 200, whether the agent is a moving object or a non-moving object, are the destination of the movement message. For this reason, the message filter 314 is provided one by one in all the agent simulators 200 comprising the MAS system 100.

The broadcast distribution network 312 is connected directly with the agent simulator 200 that is in the same subnet and connected with the agent simulator 200 that is in a different subnet via the movement message gateway 318. The movement message transmitted from the agent simulator 200 in the same subnet is distributed directly to all message filters 314. The movement message transmitted from the agent simulator 200 in the different subnet is distributed to all message filters 314 via the movement message gateway 318. The message filter 314 selects and receives the movement messages required by the agent simulator 200 that the message filter 314 is in charge of and stores them in the message queue 316. The message queue 316 transmits the stored movement messages to the agent simulator 200 that the message queue 316 is in charge of for the same time interval as the time interval at the time of reception.

### 5. Aggregation and Evaluation of Simulation Results by MAS System

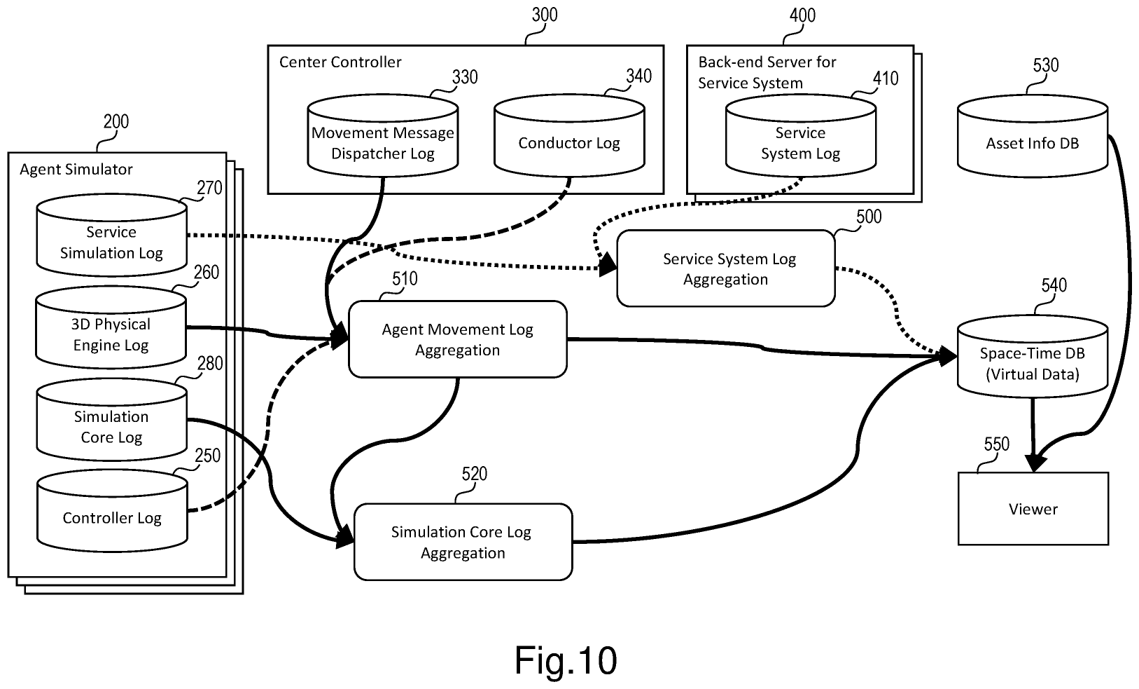

By performing the simulation with the MAS system 100, various data about the target world of the simulation can be obtained. FIG. 10 shows a configuration for aggregating and evaluating simulation results by the MAS system 100.

The MAS system 100 provides a data logger at each location for storing a log of the simulated data. The agent simulator 200 is provided with a data logger 250, 260, 270, 280. The data logger 250 stores data logs in the transmit/receive controller 210 (controller logs). The data logger 260 stores data logs in the 3D physical engine 220 (3D physical engine logs). The data logger 270 stores data logs in the service system client simulator 230 (service simulation logs). The data logger 280 stores data logs in the simulator core 240 (simulation core logs).

The center controller 300 is provided with a data logger 330, 340. The data logger 330 stores data logs in the movement message dispatcher 310 (movement message dispatcher logs). The data logger 340 stores data logs in the simulation conductor 320 (conductor logs).

The back-end server 400 is provided with a data logger 410. The data logger 410 stores data logs in the back-end server 400 (service system logs).

If the simulation is interrupted, the simulation conductor 320 can rewind and restart the simulation from any time in the past by using the data logs stored in each of the data loggers described above.

The MAS system 100 includes a service system log aggregating unit 500, an agent movement log aggregating unit 510, a simulation core log aggregating unit 520, an asset information database 530, a space-time database 540, and a viewer 550. They are installed on a computer for evaluation of simulation results.

The service system log aggregating unit 500 collects data logs from the data logger 270, 410. These data logs collected in the service system log aggregating unit 500 are data logs related to the service system. From these data logs, it is possible to evaluate whether the service was properly provided. It is also possible to evaluate the points of interest in providing services, including the utilization rate of service resources such as logistics robots.

The agent movement log aggregating unit 510 collects data logs from the data logger 250, 260, 330, 340. These data logs collected in the agent movement log aggregating unit 510 are data logs related to agent movement. From these data logs, the correct operation of the agent can be confirmed. It is also possible to check for problems such as overlapping agents. When an error occurs during the simulation, the time range in which the simulation content is assumed to be valid can be output from the data logs.

The simulation core log aggregating unit 520 collects data logs from the data logger 280 and the agent movement log aggregating unit 510. These data logs collected in the simulation core log aggregating unit 520 are data logs related to the points of interest in the simulation. From these data logs, it is possible to evaluate the points of interest such as the density of a person if the simulation is about a pedestrian, and the internal judgment result if the simulation is about a robot.

The asset information database 530 stores BIM/CIM data or three-dimensional information of a fixed object such as a building converted from BIM/CIM data and stores three-dimensional information of each agent.

The space-time database 540 stores virtual data for simulation. The evaluation results based on the data logs aggregated by the service system log aggregating unit 500, the agent movement log aggregating unit 510, and the simulation core log aggregating unit 520 are reflected to the virtual data in the space-time database 540.

The viewer 550 displays the virtual world 2 on the monitor using the three-dimensional information of the fixed object and the agent stored in the asset information database 530 and the virtual data stored in the space-time database 540.

### 6. Physical Configuration of MAS System

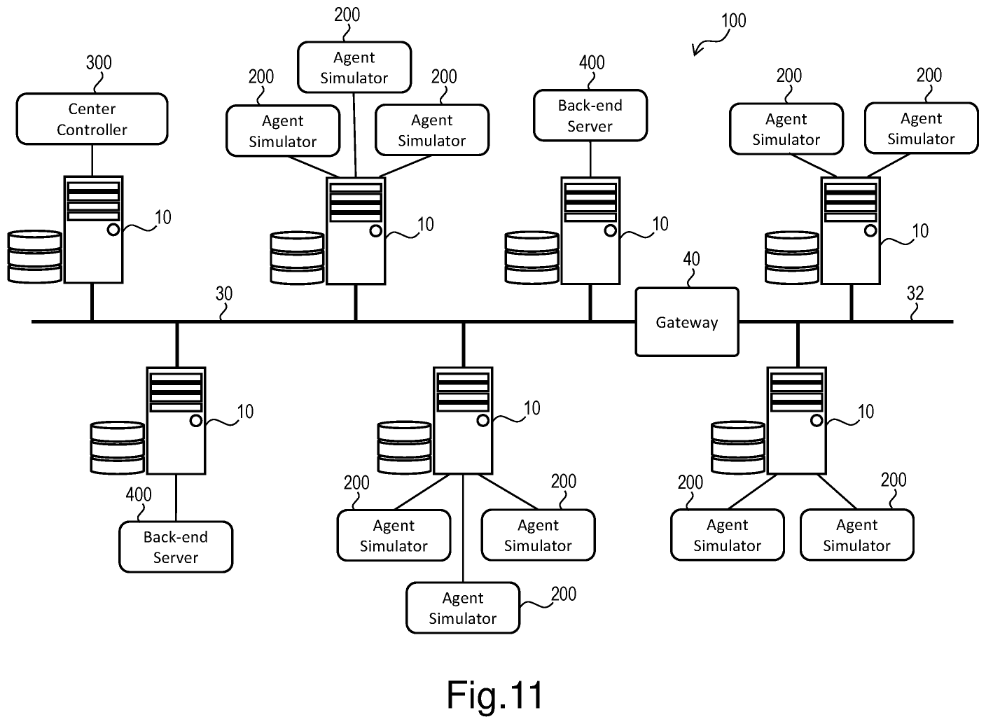

The physical configuration of the MAS system 100 will be described. FIG. 11 is a diagram illustrating an example of a physical configuration of the MAS system 100. The MAS system 100 may comprise, for example, a plurality of computers 10 arranged on the same subnet 30. Further, by connecting the subnet 30 and another subnet 32 by a gateway 40, the MAS system 100 can be expanded to a plurality of computers 10 located on the subnet 32.

In the example shown in FIG. 11, the center controller 300, which is software, is installed on one computer 10. However, the functions of the center controller 300 may be distributed to a plurality of computers 10.

The MAS system 100 includes a plurality of back-end servers 400. In the example shown in FIG. 11, each back-end server 400 is installed on a separate computer 10. However, the function of the back-end server 400 may be distributed to a plurality of computers 10. Further, a plurality of back-end servers 400 may be installed on one computer 10 by a virtualization technique for dividing one server into a plurality of servers.

In the example shown in FIG. 11, a plurality of agent simulators 200 are installed on one computer 10. Virtualization technology can be used as a method of independently operating a plurality of agent simulators 200 on a single computer 10. The virtualization technology can be a virtual machine or a container virtualization. A plurality of agent simulators 200 of the same type may be installed on one computer 10, or a plurality of agent simulators 200 of different types may be installed. Note that only one agent simulator 200 may be installed on one computer 10.

As described above, the MAS system 100 employs parallel distributed processing using a plurality of computers 10 rather than processing by a single computer. This prevents the computing power from limiting the number of agents appearing in the virtual world 2 and the computing power from limiting the number of services provided in the virtual world 2. That is, according to the MAS system 100, a large-scale simulation by parallel distributed processing is possible.

### 7. Other Embodiment

An observation agent may be provided to observe the virtual world 2 from outside. The observation agent may be, for example, a non-moving object, such as a street-corner camera, or a moving object, such as a drone with a camera.

What is claimed is:

1. A system for simulating a target world using a plurality of agents interacting with each other, comprising:
a plurality of agent simulators provided for each of the plurality of agents and configured to simulate a state of each of the plurality of agents while causing the plurality of agents to interact with each other by exchange of messages; and
a center controller configured to communicate with the plurality of agent simulators to relay transmission and reception of the messages between the plurality of agent simulators,
wherein the plurality of agents include a plurality of types of agents including types having different time granularity; and each of the plurality of agent simulators is configured to transmit a message to the center controller at a transmission time interval corresponding to time granularity of a target agent to be simulated.

2. The system according to claim 1, wherein the center controller is configured to transmit the messages received from each of the plurality of agent simulators at a same time interval as a time interval at which the messages are received.

3. The system according to claim 1, wherein the center controller is configured to transmit the messages received from each of the plurality of agent simulators by a broadcast.

4. The system according to claim 1, wherein the plurality of types of agents include a person operated by a VR system; and each of the plurality of agent simulators executes a simulation in real time.

5. A method for simulating a target world using a plurality of agents interacting with each other, comprising:
exchanging messages between a plurality of agent simulators provided for each of the plurality of agents;
simulating a state of each of the plurality of agents while causing the plurality of agents to interact with each other by exchange of the messages; and
relaying transmission and reception of the messages between the plurality of agent simulators by a center controller configured to communicate with the plurality of agent simulators,
wherein the plurality of agents include a plurality of types of agents including types having different time granularity; and the method comprises causing each of the plurality of agent simulators to transmit a message to the center controller at a transmission time interval corresponding to time granularity of a target agent to be simulated.

6. The method according to claim 5, wherein the method comprises causing the center controller to transmit the messages received from each of the plurality of agent simulators at a same time interval as a time interval at which the messages are received.

7. The method according to claim 5, wherein the method comprises causing the center controller to transmit the messages received from each of the plurality of agent simulators by a broadcast.

8. The method according to claim 5, wherein the plurality of types of agents include a person operated by a VR system; and the method comprises causing each of the plurality of agent simulators to execute a simulation in real time.
